(19) United States
(12) Patent Application Publication
(10) Pub. No.: US 2025/0336771 A1
(43) Pub. Date: Oct. 30, 2025

(54) SEMICONDUCTOR DEVICE AND SEMICONDUCTOR PACKAGE INCLUDING THE SAME

(71) Applicant: SAMSUNG ELECTRONICS CO., LTD., SUWON-SI (KR)

(72) Inventors: Chungwon Jeong, Suwon-si (KR); Sung Won Kim, Suwon-si (KR); Cheol-Hee Park, Suwon-si (KR); Sungjun Cho, Suwon-si (KR); Sangmin Han, Suwon-si (KR)

(21) Appl. No.: 19/019,636

(22) Filed: Jan. 14, 2025

(30) Foreign Application Priority Data
Apr. 25, 2024 (KR) 10-2024-0055496

(51) Int. Cl. H01L 23/48; H01L 21/768; H01L 23/528; H01L 25/065; H10D 30/67; H10D 62/10; H10D 62/13; H10D 64/01

(52) U.S. Cl. CPC H01L 23/481; H01L 21/76831; H01L 21/76877; H01L 23/528; H01L 25/0657; H10D 30/6735; H10D 62/121; H10D 62/151; H10D 64/017; H01L 2225/06544

(57) ABSTRACT

A semiconductor device includes: a substrate including a cell region and a connection region, and extending in a first direction, wherein the connection region includes a through-region; active regions protruding vertically from the first surface of the substrate; source/drain regions spaced apart from each other on the substrate in the first direction, and including: first source/drain regions having a portion at least partially overlapping the through-region, and second source/drain regions disposed on at least one side of the active regions on the substrate; first gate structures intersecting the active regions; a front structure including a front conductive pattern; a backside structure including a backside conductive pattern; and a through-electrode structure filling the through-region, and electrically connected to the front conductive pattern and the backside conductive pattern, and wherein at least a portion of a lower region of the through-electrode structure is in contact with the first source/drain regions.

### CROSS-REFERENCE TO RELATED APPLICATION

This application claims priority under 35 U.S.C. 119 Korean Patent Application No. 10-2024-0055496 filed on Apr. 25, 2024, in the Korean Intellectual Property Office, the disclosure of which is incorporated by reference herein in its entirety.

### TECHNICAL FIELD

The present inventive concept relates to a semiconductor device and a semiconductor package including the same.

### DISCUSSION OF THE RELATED ART

As demand for high performance, high speed, and/or multifunctionality of semiconductor devices increases, the degree of integration of a semiconductor device has increased. In manufacturing fine-patterned semiconductor devices in response to the trend of increased integration of semiconductor devices, it has become desirable to implement patterns having a fine width or a fine separation distance therebetween.

### SUMMARY

According to an example embodiment of the present inventive concept, a semiconductor device includes: a substrate including a cell region and a connection region and extending in a first direction, wherein the substrate has a first surface and a second surface opposing each other, wherein the connection region includes a through-region, and has a first side and a second side opposing each other in the first direction with the through-region interposed therebetween; active regions protruding vertically from the first surface of the substrate, in a first region, which is adjacent to the first side of the connection region, and a second region, which is adjacent to the second side of the connection region; source/drain regions spaced apart from each other on the substrate in the first direction, wherein the source/drain regions include: first source/drain regions having a portion at least partially overlapping the through-region, and second source/drain regions disposed on at least one side of the active regions on the substrate; first gate structures intersecting the active regions and disposed on the active regions, wherein the first gate structures include a gate electrode and a gate capping layer on the gate electrode, and extends in a second direction; a front structure including a front conductive pattern disposed on the first surface of the substrate; a backside structure including a backside conductive pattern disposed on the second surface of the substrate; and a through-electrode structure extending by filling the through-region of the substrate, and electrically connected to the front conductive pattern of the front structure and the backside conductive pattern of the backside structure, and wherein at least a portion of a side surface of a lower region of the through-electrode structure is in contact with the first source/drain regions.

According to an example embodiment of the present inventive concept, a semiconductor device includes: a substrate including a cell region and a dummy region and extending in a first direction, wherein the substrate has a first surface and a second surface opposing each other, wherein the dummy region includes a through-region, and has a first side and a second side opposing each other in the first direction with the through-region interposed therebetween; active regions protruding vertically from the first surface of the substrate, in a first region, which is adjacent to the first side of the dummy region, and a second region, which is adjacent to the second side of the dummy region; source/drain regions spaced apart from each other on the substrate in the first direction, wherein portions of the source/drain regions are on at least one side of the active regions on the substrate; dummy gate structures intersecting the active regions on the active regions, and including a gate electrode and a gate capping layer on the gate electrode, wherein the dummy gate structures extend in a second direction; a front structure including a front conductive pattern disposed on the first surface of the substrate; a backside structure including a backside conductive pattern disposed on the second surface of the substrate; a separation structure disposed between the source/drain regions that are adjacent to each other between the first region and the second region, and extending on the substrate in the second direction; and a through-electrode structure extending by filling the through-region of the substrate, and contacting the front conductive pattern of the front structure and the backside conductive pattern of the backside structure, wherein at least a portion of the separation structure is in contact with at least a portion of an external circumferential surface of the through-electrode structure in the through-region.

According to an example embodiment of the present inventive concept, a semiconductor device includes: a substrate including a cell region and a connection region and extending in a first direction, wherein the substrate has a first surface and a second surface opposing each other, wherein the connection region includes a through-region, and has a first side and a second side opposing each other in the first direction with the through-region interposed therebetween; active regions protruding vertically from the first surface of the substrate, in a first region, which is adjacent to the first side of the connection region, and a second region, which is adjacent to the second side of the connection region; impurity regions in which at least some thereof is on at least one side of the active regions on the substrate, wherein the impurity regions are spaced apart from each other on the substrate in the first direction; a front structure including a front conductive pattern disposed on the first surface of the substrate; a backside structure including a backside conductive pattern disposed on the second surface of the substrate; separation structures disposed between the impurity regions that are adjacent to each other between the first region and the second region, and extending on the substrate in a second direction; and a through-electrode structure extending by filling the through-region of the substrate, and electrically connecting the front structure and the backside structure to each other, wherein at least a portion of the separation structures is in contact with at least a portion of an external circumferential surface of the through-electrode structure in the through-region.

### BRIEF DESCRIPTION OF DRAWINGS

The above and other aspects and features of the present inventive concept will become more apparent by describing in detail example embodiments thereof, with reference to the accompanying drawings, in which:

FIGS. 1A and 1B are cross-sectional views illustrating a semiconductor device according to an example embodiment of the present inventive concept;

FIG. 2A is a partial enlarged view illustrating a semiconductor device according to example embodiments of the present inventive concept;

FIG. 2B is a plan view of a semiconductor device according to an example embodiment of the present inventive concept;

FIG. 2C is a partial enlarged view illustrating a semiconductor device according to example embodiments of the present inventive concept;

FIG. 3 is a partial enlarged view illustrating a semiconductor device according to example embodiments of the present inventive concept;

FIG. 4A is a partial enlarged view illustrating a semiconductor device according to example embodiments of the present inventive concept;

FIG. 4B is a plan view of a semiconductor device according to an example embodiment of the present inventive concept;

FIG. 5A is a partial enlarged view illustrating a semiconductor device according to example embodiments of the present inventive concept;

FIG. 5B is a plan view of a semiconductor device according to an example embodiment of the present inventive concept;

FIG. 6A is a partial enlarged view illustrating a semiconductor device according to example embodiments of the present inventive concept;

FIG. 6B is a plan view of a semiconductor device according to an example embodiment of the present inventive concept;

FIG. 7 is a cross-sectional view illustrating a semiconductor device according to an example embodiment of the present inventive concept;

FIG. 8 is a plan view of a semiconductor device according to an example embodiment of the present inventive concept;

FIG. 9 is a cross-sectional view illustrating a semiconductor device according to an example embodiment of the present inventive concept;

FIG. 10 is a plan view of a semiconductor device according to an example embodiment of the present inventive concept;

FIG. 11 is a cross-sectional view illustrating a semiconductor device according to an example embodiment of the present inventive concept;

FIG. 12 is a partial enlarged view illustrating a semiconductor device according to example embodiments of the present inventive concept;

FIG. 13 is a cross-sectional view illustrating a semiconductor device according to an example embodiment of the present inventive concept;

FIG. 14 is a cross-sectional view of a semiconductor package according to an example embodiment of the present inventive concept;

FIGS. 15A, 15B, 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, and 27B are vertical cross-sectional views illustrating a method of manufacturing a semiconductor device according to an example embodiment of the present inventive concept; and

FIGS. 28A, 28B, 29A, 29B, 30A, 30B, 31A, 31B, 32A, 32B, 33A, and 33B are vertical cross-sectional views illustrating a method of manufacturing a semiconductor device according to an example embodiment of the present inventive concept.

### DETAILED DESCRIPTION OF THE EMBODIMENTS

Hereinafter, the terms such as “upper,” “intermediate,” and “lower” may be replaced with other terms such as “first,” “second,” and “third” and may be used to describe components of the specification. The terms such as “first,” “second,” and “third” may be used to describe various components, but the components are not limited by the terms, and the “first component” could be termed “second component.”

Hereinafter, example embodiments of the present inventive concept will be described with reference to the accompanying drawings.

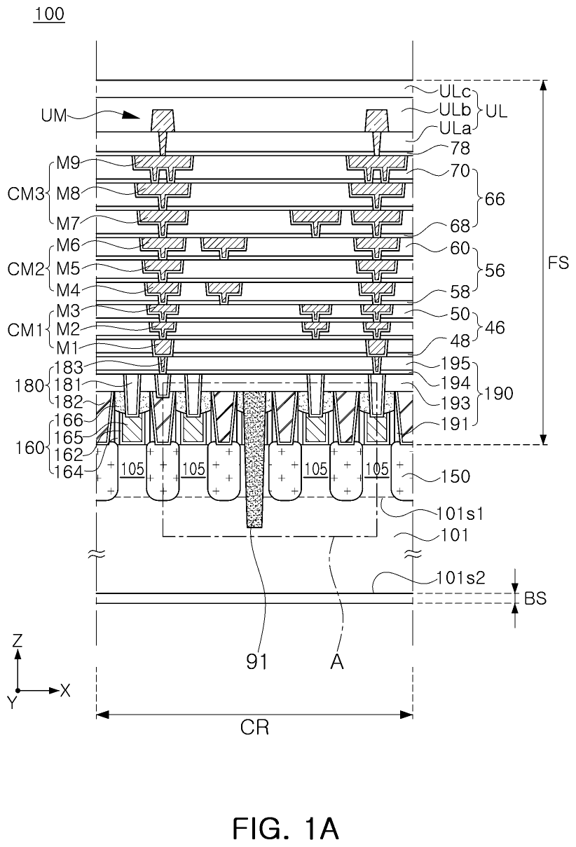

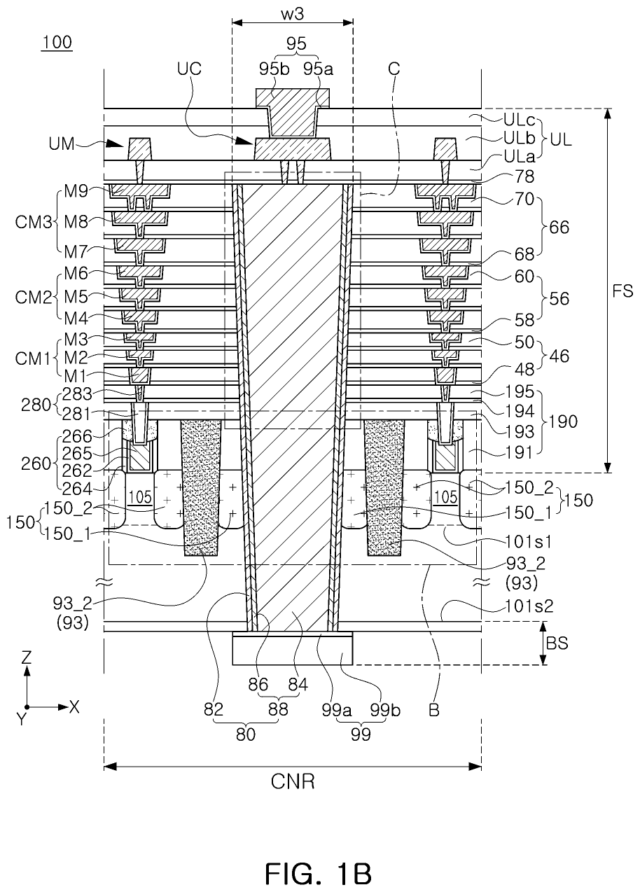

FIGS. 1A and 1B are cross-sectional views illustrating a semiconductor device according to an example embodiment of the present inventive concept.

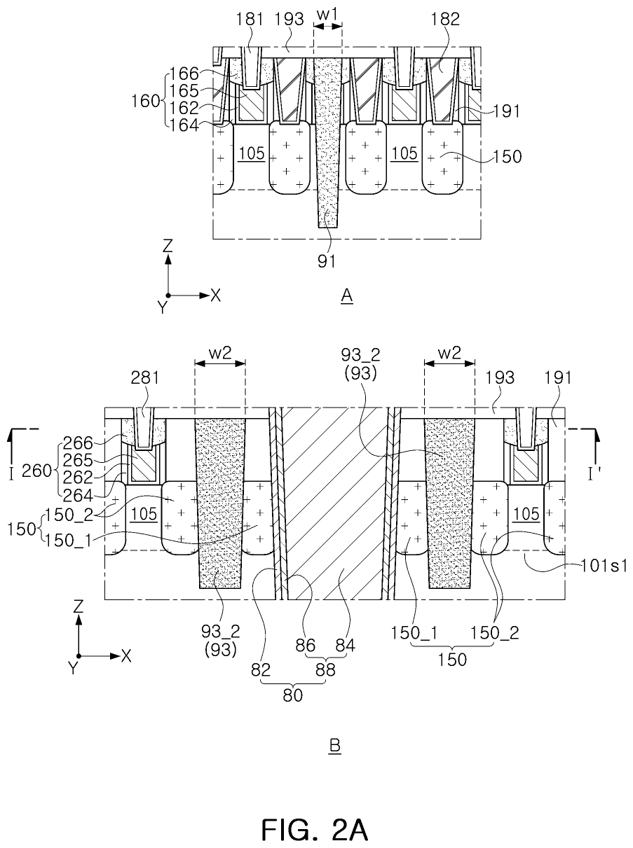

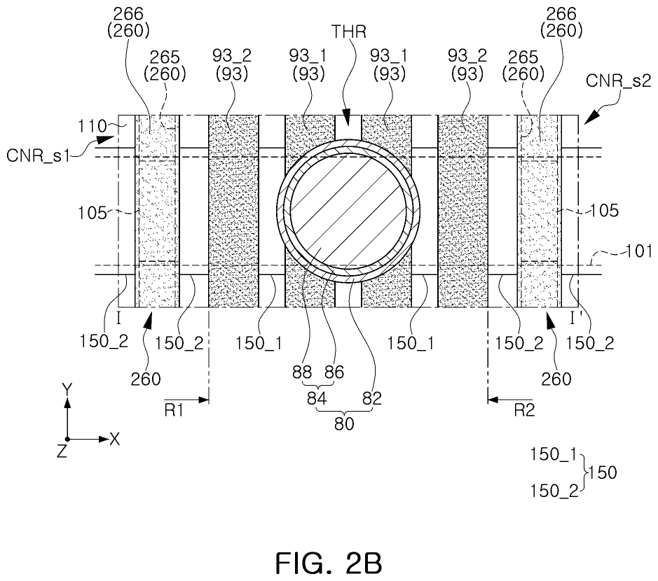

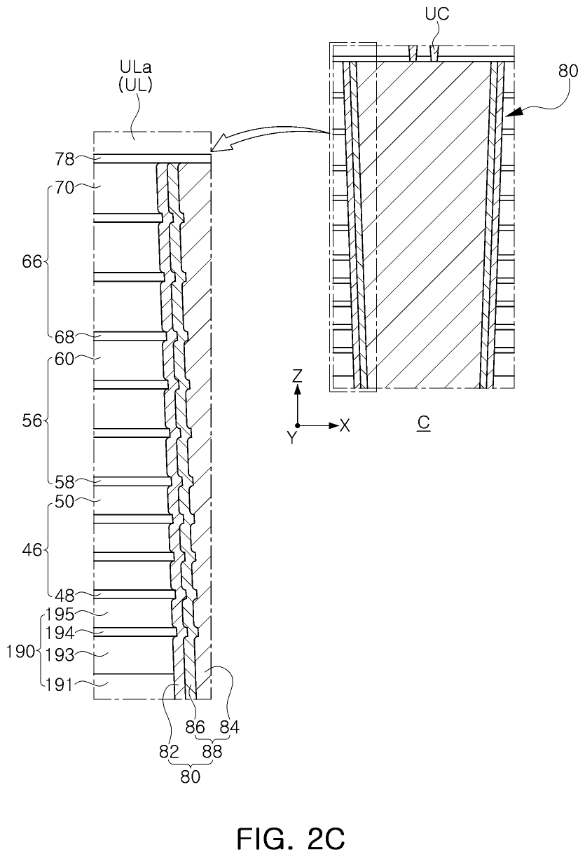

FIG. 2A is a partial enlarged view illustrating a semiconductor device according to example embodiments of the present inventive concept. FIG. 2A is a partial enlarged view of region ‘A’ of FIG. 1A and region ‘B’ of FIG. 1B.

FIG. 2B is a plan view of a semiconductor device according to an example embodiment of the present inventive concept. FIG. 2B is a plan view taken along line II′ of a partially enlarged view of region B illustrated in FIG. 2A.

FIG. 2C is a partial enlarged view illustrating a semiconductor device according to example embodiments of the present inventive concept. FIG. 2C is a partial enlarged view of region ‘C’ of FIG. 1B.

Referring to FIGS. 1A, 1B, 2A, 2B and 2C, a semiconductor device 100 according to an example embodiment of the present inventive concept may include a substrate 101 including a cell region CR and a connection region CNR and having a first surface 101s1 and a second surface 101s2 opposing each other, a front structure FS on the first surface 101s1 of the substrate 101, and a backside structure BS on the second surface 101s2 of the substrate 101. The semiconductor device 100 may further include a through-electrode structure 80 disposed in the connection region CNR of the substrate 101. According to an example embodiment of the present inventive concept, the semiconductor device 100 may further include a separation structure 90.

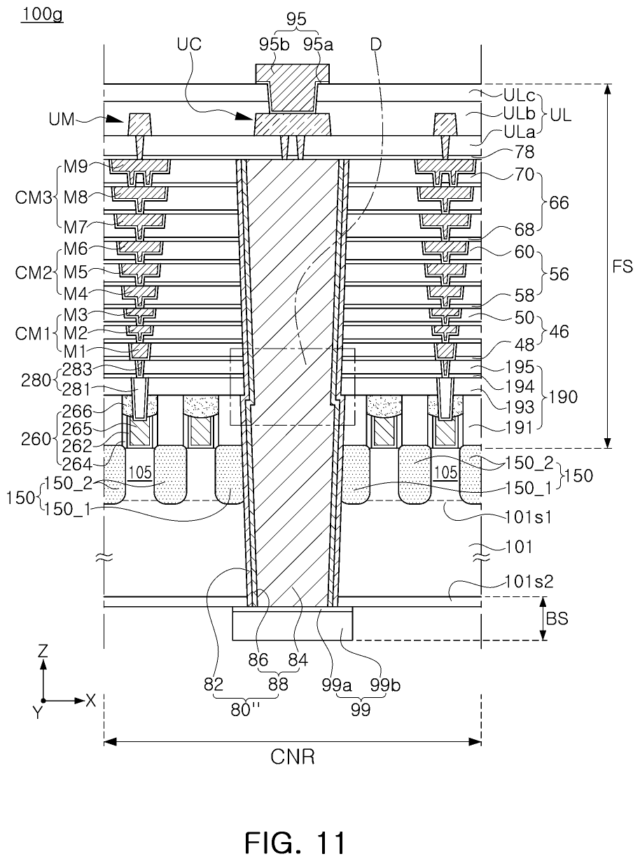

The backside structure BS may include a backside insulating layer 97 disposed below the second surface 101s2 of the substrate 101. In the connection region CNR of the substrate 101, the backside structure BS may further include a backside conductive pattern 99 disposed on a lower surface of the backside insulating layer 97. According to an example embodiment of the present inventive concept, the backside conductive pattern 99 may be disposed in plural below the second surface 101s2 of the substrate 101 (see FIG. 11).

The backside conductive pattern 99 may include a first conductive layer 99a and a second conductive layer 99b below the first conductive layer 99a. The second conductive layer 99b may include copper.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may include, for example, a silicon substrate, a silicon-on-insulator (SOI) substrate, a germanium substrate, a germanium-on-insulator (GOI) substrate, a silicon-germanium substrate, or a substrate including an epitaxial layer.

The substrate 101 may include a cell region CR and a connection region CNR. Here, the connection region CNR may be referred to as a dummy region.

The cell region CR may be a region in which a circuit element including a gate structure 160 is disposed.

The connection region CNR may be a region in which a dummy pattern including a dummy gate structure 260 is formed. The connecting region CNR may include a through-region THR, and may have a first side CNR_s1 and a second side CNR_s2. The through-region THR may be a region filled by the through-electrode structure 80. The first side CNR_s1 and the second side CNR_s2 may be sides opposing each other in a first direction, for example, an X-direction, with the through-region THR interposed therebetween. The connection region CNR may have a first region R1, which is adjacent to the first side CNR_s1, and a second region R2, which is adjacent to the second side CNR_s2. In other words, the first region R1 and the second region R2 may be defined as regions opposing each other in the first direction, for example, the X-direction, with the through-region THR interposed therebetween.

Active regions 105 may be defined as active fins that protrude from the first surface 101s1 of the substrate 101 in a vertical direction. Accordingly, the active regions 105 may have a structure of the active fin. The active regions 105 may be defined by device isolating layers 110. The device isolating layers 110 may extend in the first direction, for example, the X-direction, on the substrate 101 with the active regions 105 interposed therebetween. The device isolating layers 110 may be formed by, for example, a shallow trench isolation (STI) process. The device isolating layers 110 may be, for example, oxide, nitride, or combinations thereof.

In the cell region CR, the active regions 105 may be spaced apart from each other in the first direction, for example, the X-direction, on the first surface 101s1 of the substrate 101.

In the first region R1 and the second region R2 of the connection region CNR, the active regions 105 may protrude from the first surface 101s1 of the substrate 101 in a vertical direction, for example, in the Z-direction. In each of the first region R1 and the second region R2, although one active region 105 is illustrated as being formed, the present inventive concept is not limited thereto. For example, a plurality of active regions 105 may be formed in each of the first region R1 and the second region R2.

Source/drain regions 150 may be disposed on both sides of the active region 105 on the substrate 101. The source/drain regions 150 may be a semiconductor layer including, for example, silicon (Si) or silicon germanium (SiGe), and may include impurities of different types and/or concentrations. Accordingly, the source/drain region 150 may be referred to as an impurity region.

In the cell region CR, the source/drain regions 150 may be spaced apart from each other in the first direction, for example the X-direction, on the substrate 101 with the active region 105 interposed therebetween. The source/drain regions 150 may serve as a source region or a drain region of the semiconductor device 100.

In the connection region CNR, the source/drain regions 150 may be defined as having a first source/drain region 150_1 and a second source/drain region 150_2.

The first source/drain region 150_1 may be a source/drain region that is at least partially disposed in the through-region THR and that is a portion at least partially overlapping the through-region THR vertically. For example, a side portion of the first source/drain region 150_1 may be in contact with a side surface of a lower region of the through-electrode structure 80.

The second source/drain region 150_2 may be a source/drain region disposed in the first region R1 and the second region R2. For example, the second source/drain region 150_2 may be a source/drain region that is disposed on both sides of the active regions 105 of the first region R1 and the second region R2 and that does not have a portion overlapping the through-region THR.

A gate structure 160 may be disposed on the active region 105, may include a gate electrode 165, a gate dielectric layer 162 between the gate electrode 165 and the active region 105, gate spacer layers 164 on side surfaces of the gate electrode 165 and a gate capping layer 166.

The gate dielectric layer 162 may be disposed between the active region 105 and the gate electrode 165, and may be arranged to cover at least portions of surfaces of the gate electrode 165. For example, the gate dielectric layer 162 may be arranged to surround all surfaces of the gate electrode 165 except an uppermost surface of the gate electrode 165. The gate dielectric layer 162 may extend between the gate electrode 165 and the gate spacer layers 164, but the present inventive concept is not limited thereto. For example, the gate dielectric layer 162 may include oxide, nitride, or a high-material. The high-material may refer to a dielectric material having a dielectric constant that is higher than that of a silicon oxide film (SiO₂), and the high-k material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrode 165 may be disposed on gate dielectric layer 162. The gate electrode 165 may include a conductive material, and may include, for example, a metal nitride such as titanium nitride (TiN), tantalum nitride (TaN) or tungsten nitride (WN), and/or a metal material such as aluminum (Al), tungsten (W) or molybdenum (Mo) or a semiconductor material such as doped polysilicon. For example, the gate electrode layer 165 may be formed of two or more multiple layers.

The gate spacer layers 164 may be disposed on both side surfaces of the gate electrode layer 165. The gate spacer layers 164 may insulate the source/drain regions 150 and the gate electrode 165 from each other. The gate spacer layers 164 may have a multilayer structure according to example embodiments of the present inventive concept. For example, the gate spacer layers 164 may be formed of oxide, nitride, and oxynitride, and may be formed of, especially a low dielectric constant film. For example, the gate spacer layers 164 may include at least one of SiO, SiN, SiCN, SiOC, SiON, and SiOCN.

The gate capping layer 166 may be disposed on an upper surface of the gate electrode layer 165, and a lower surface and side surfaces of the gate capping layer 166 may be surrounded by the gate electrode layer 165 and the gate spacer layers 164, respectively. The gate capping layer 166 may be formed of, for example, oxide, nitride, and oxynitride.

In the cell region CR, the gate structure 160 may be arranged to extend in a second direction, for example, the Y-direction, on the active region 105. The active region 105 may be formed as a channel region of a transistor.

In the connection region CNR, the gate structure may be referred to as a dummy gate structure 260. The dummy gate structure 260 may include a dummy gate electrode 265, a gate dielectric layer 262, gate spacer layers 264, and a gate capping layer 266.

The dummy gate structure 260 may be disposed on the active regions 105 of the first region R1 and the second region R2. Accordingly, the second source/drain regions 150_2 may be disposed on both sides (e.g., opposing sides) of the dummy gate structure 260 on the substrate 101.

The dummy gate structure 260 of the connection region CNR may be electrically insulated from the gate structure 160 of the cell region CR.

The front structure FS may include lower interlayer insulating layers 190 covering the gate structures 160 and 260 on the first surface 101s1 of the substrate 101. The lower interlayer insulating layers 190 may include a first lower interlayer insulating layer 191, which is disposed on side surfaces of the gate structures 160 and 260, and a second lower interlayer insulating layer 193, which is disposed on the first lower interlayer insulating layer 191 and covering upper surfaces of the gate structures 160 and 260. At least one of the first or second lower interlayer insulating layers 191 or 193 may include silicon oxide. For example, each of the first and second lower interlayer insulating layers 191 and 193 may be formed of silicon oxide.

The lower interlayer insulating layers 190 may further include a lower insulating barrier layer 194, which is disposed on the second lower interlayer insulating layer 193, and a third lower interlayer insulating layer 195, which is disposed on the lower insulating barrier layer 194.

The lower insulating barrier layer 194 may be a single layer or multiple layers. For example, the lower insulating barrier layer 194 may include at least one of AlN, SiCO, or SiCN. For example, the lower insulating barrier layer 194 may include at least one of SiCO and SiCN.

The third lower interlayer insulating layer 195 may include a low-κ dielectric material.

The front structure FS may further include contact plugs 180 and 280 electrically connected to circuit elements that include the gate structures 160 and 260.

The contact plugs 180 in the cell region CR may include a first contact plug 181 electrically connected to the gate structure 160, a second contact plug 182 electrically connected to the source/drain region 150, and a third contact plug 183 penetrating through the third lower interlayer insulating layer 195 on the second contact plug 182. A contact plug penetrating through the second lower interlayer insulating layer 193 on the second contact plug 182 may also be referred to as the second contact plug 182. A contact plug penetrating through the third lower interlayer insulating layer 195 on the first contact plug 181 may also be referred to as the third contact plug 183.

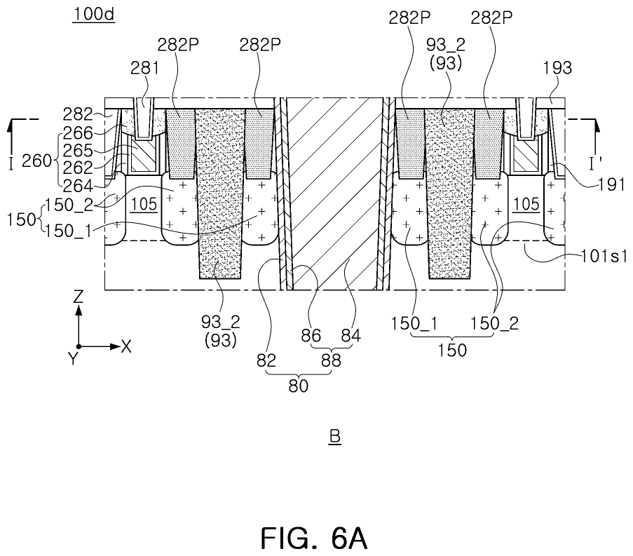

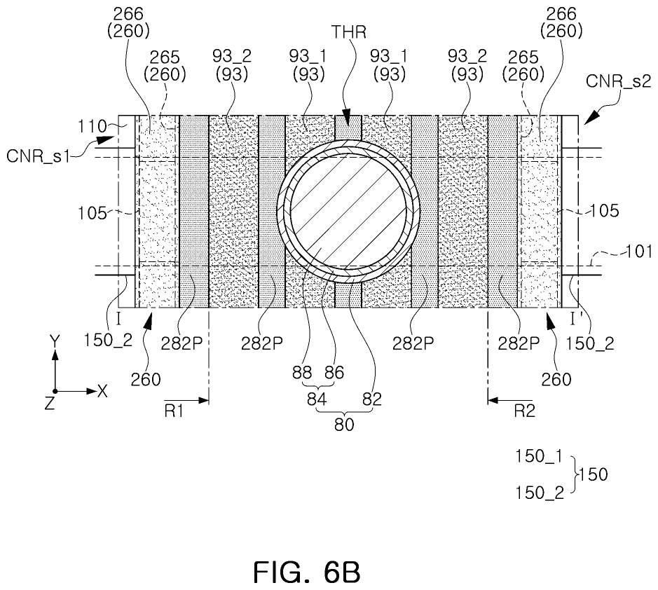

The contact plugs 280 of the connection region CNR may include a first contact plug 281, which is electrically connected to the dummy gate structure 260, and a third contact plug 283, which penetrates through the third lower interlayer insulating layer 195 on the first contact plug 281. According to an example embodiment of the present inventive concept, the front structure FS may further include a second contact plug 282 that is electrically connected to the source/drain region 150 in the connection region CNR (see FIGS. 6A and 6B).

The front structure FS may include a first insulating structure 46 on the lower interlayer insulating layers 190, a second insulating structure 56 on the first insulating structure 46, a third insulating structure 66 on the second insulating structure 56, and an upper insulating structure UL on the third insulating structure 66. The front structure FS may further include an upper insulating barrier layer 78 that is disposed between the upper insulating structure UL and the third insulating structure 66. The upper insulating barrier layer 78 may include, for example, SiCN or SiN.

The first insulating structure 46 may include first insulating barrier layers 48 and first intermetallic insulating layers 50 alternately and repeatedly stacked on the lower interlayer insulating layers 190. The second insulating structure 56 may include second insulating barrier layers 58 and second intermetallic insulating layers 60 alternately and repeatedly stacked on the first insulating structure 46. The third insulating structure 66 may include third insulating barrier layers 68 and third intermetallic insulating layers 70 alternately and repeatedly stacked on the second insulating structure 56. The third insulating structure 66 may have a thickness greater than a thickness of the second insulating structure 56, and the second insulating structure 56 may have a thickness greater than a thickness of the first insulating structure 46. At least one of the first to third insulating barrier layers 48, 58 and 68 may include at least one of SiCO or SiCN. The first to third intermetallic insulating layers 50, 60 and 70 may include a low-κ dielectric material.

The upper insulating structure UL may include a first upper insulating layer ULa, a second upper insulating layer ULb, and a third upper insulating layer ULc which are sequentially stacked on the third insulating structure 66. For example, at least one of the first to third upper insulating layers ULa, ULb and ULc may include at least one of silicon oxide or silicon nitride. In an example embodiment of the present inventive concept, the first upper insulating layer ULa and the second upper insulating layer ULb may include silicon oxide. The third upper insulating layer ULc may include a material having a dielectric constant that is higher than that of dielectric constants of the first upper insulating layer ULa and the second upper insulating layer ULb, for example, silicon nitride. Here, the third upper insulating layer ULc may be formed of a passivation material that may protect the semiconductor device 100 in addition to silicon nitride.

The front structure FS may include circuit interconnection structures CM1, CM2, CM3 and UM. The circuit interconnection structures CM1, CM2, CM3 and UM may include a first circuit interconnection structure CM1, a second circuit interconnection structure CM2 on the first circuit interconnection structure CM1, a third circuit interconnection structure CM3 on the second circuit interconnection structure CM2, and an upper circuit interconnection pattern UM on the third circuit interconnection structure CM3.

The first circuit interconnection structure CM1 may be disposed within the first insulating structure 46, and may include a plurality of circuit interconnection patterns disposed on different levels from each other. For example, the first circuit interconnection structure CM1 may include first, second and third circuit interconnection patterns M1, M2 and M3 arranged on different levels from each other. Each of the second and third circuit interconnection patterns M2 and M3, among the first, second and third circuit interconnection patterns M1, M2 and M3, may include a via portion and an interconnection portion extending from the via portion, and the first circuit interconnection pattern M1 may be formed of the interconnection portion.

Throughout the specification, the term “level” may be a term used to compare relative positions when viewed based on the attached drawings of the cross-sectional structure. Accordingly, hereinafter, even if there is no additional explanation or definition of the term “level,” the term “level may be understood based on the attached drawings of the cross-sectional structure.

Each of the first, second and third circuit interconnection patterns M1, M2 and M3 may include a conductive material pattern and a conductive barrier layer covering a side surface and a bottom surface of the conductive material pattern. The conductive material pattern may include a copper material.

Each of the first, second and third circuit interconnection patterns M1, M2 and M3 may penetrate through one first insulating barrier layer 48 and one first intermetallic insulating layer 50 which are sequentially stacked. For example, any one of the first, second and third circuit interconnection patterns M1, M2 and M3 may penetrate through one first intermetallic insulating layer 50 and one first insulating barrier layer 48, which is in contact with a lower surface of the one first intermetallic insulating layer 50.

The second circuit interconnection structure CM2 may be disposed within the second insulating structure 56, and may include a plurality of circuit interconnection patterns disposed on different levels from each other. For example, the second circuit interconnection structure CM2 may include fourth, fifth and sixth circuit interconnection patterns M4, M5 and M6 disposed on different levels from each other. Each of the fourth, fifth and sixth circuit interconnection patterns M4, M5 and M6 may include a via portion and an interconnection portion extending from the via portion.

Each of the fourth, fifth and sixth circuit interconnection patterns M4, M5 and M6 may include a conductive material pattern and a conductive barrier layer covering a side surface and a bottom surface of the conductive material pattern. The conductive material pattern may include a copper material.

Each of the fourth, fifth and sixth circuit interconnection patterns M4, M5 and M6 may penetrate through one second insulating barrier layer 58 and one second intermetallic insulating layer 60 which are sequentially stacked. For example, any one of the fourth, fifth and sixth circuit interconnection patterns M4, M5 and M6 may penetrate through one second intermetallic insulating layer 60 and one second insulating barrier layer 58, which is in contact with a lower surface of the one second intermetallic insulating layer 60.

The third circuit interconnection structure CM3 may be disposed within the third insulating structure 66, and may include a plurality of circuit interconnection patterns located at different levels from each other. For example, the third circuit interconnection structure CM3 may include seventh, eighth and ninth circuit interconnection patterns M7, M8 and M9 arranged on different levels from each other. The seventh, eighth and ninth circuit interconnection patterns M7, M8 and M9 may include a via portion and an interconnection portion extending from the via portion.

Each of the seventh, eighth and ninth circuit interconnection patterns M7, M8 and M9 may include a conductive material pattern and a conductive barrier layer covering a side surface and a bottom surface of the conductive material pattern. The conductive material pattern may include a copper material.

Each of the seventh, eighth and ninth circuit interconnection patterns M7, M8 and M9 may penetrate through one third insulating barrier layer 68 and one third intermetallic insulating layer 70 which are sequentially stacked. For example, any one of the seventh, eighth and ninth circuit interconnection patterns M7, M8 and M9 may penetrate thought one third intermetallic insulating layer 70 and one third insulating barrier layer 68 in contact with a lower surface of the one third intermetallic insulating layer 70.

The upper circuit interconnection pattern UM may include a via portion, which penetrates through the first upper insulating layer ULa, and an interconnection portion, which extends from the via portion and disposed on the first upper insulating layer ULa. The upper circuit interconnection pattern UM may include a conductive material pattern and a conductive barrier layer covering a bottom surface of the conductive material pattern. The conductive material pattern may include aluminum. The second upper insulating layer ULb may cover an upper surface and a side surface of the interconnection portion of the upper circuit interconnection pattern UM.

A lateral slope of the interconnection portion of the upper circuit interconnection pattern UM may be different from lateral slopes of each of the interconnection portions of the lower circuit interconnection structures CM1, CM2 and CM3. For example, a side surface of the interconnection portion of the upper circuit interconnection pattern UM has a positive slope, and each side surface of the interconnection portions of the lower circuit interconnection structures CM1, CM2 and CM3 may have negative slopes. Here, the positive slope of the side surface may be a slope of a side surface in which a width of a structure decreases from a lower surface to an upper surface, and the negative slope of the side surface may be a slope of a side surface in which a width of a structure increases from the lower surface to the upper surface.

In the connection region CNR, the front structure FS may further include an upper

connection pattern UC (or ‘front conductive pattern’) on the third insulating structure 66. The upper connection pattern UC may be disposed on substantially the same level as the upper circuit interconnection pattern UM. The upper connection pattern UC may include one or a plurality of via portion penetrating through the third intermetallic insulating layer 70 or a connection portion extending from the one or plurality of via portions. The upper connection pattern UC may include the same material as the upper circuit interconnection pattern UM, for example, the conductive material pattern of the upper circuit interconnection pattern UM, and the conductive barrier layer covering a lower surface of the conductive material pattern.

In the connection region CNR, the front structure FS may further include a front pad 95 penetrating a portion of the upper insulating structure UL and contacting the upper connection pattern UC. The front pad 95 may include a liner layer 95a and a pad pattern 95b on the liner layer 95a. The pad pattern 95b may be a conductive bump. For example, the pad pattern 95b may include at least one of copper, nickel, gold, and solder. A width of the front pad 95 may be smaller than the width of the backside conductive pattern 99.

The separation structures 90 may include a separation structure 91 in the cell region CR and a separation structure 93 in the connection region CNR.

In the cell region CR, the separation structure 91 may be disposed between the source/drain regions 150 that are adjacent to each other on the substrate 101, and may be arranged to extend in the second direction, for example, the Y-direction.

In the connection region CNR, the separation structure 93 may include a first separation structure 93_1 and a second separation structure 93_2 between the first region R1 and the second region R2.

The first separation structure 93_1 may be disposed between first source/drain regions 150_1 that are adjacent to each other on the substrate 101, and may be arranged to extend in the second direction, for example, the Y-direction. For example, the first separation structure 93_1 may be defined as a separation structure vertically overlapping the through-region THR among the separation structures 93. Both side surfaces of the first separation structure 93_1 may be in contact with side surfaces of the first source/drain regions 150_1 that are adjacent to each other.

The second separation structure 93_2 may be disposed between the first source/drain region 150_1 and the second source/drain region 150_2, and may be arranged to extend in the second direction, for example, the Y-direction. For example, the second separation structure 93_2 may be between the first region R1 and the through-region THR, and between the second region R2 and the through-region THR. In other words, the second separation structure 93_2 may be defined as a separation structure that is spaced apart from the through-region THR among the separation structures 93 and does not overlap the through-region THR. Both side surfaces of the second separation structure 93_2 may be in contact with one side surface of the first source/drain region 150_1 and one side surface of the second source/drain region 150_2, respectively.

The separation structures 90 may extend in a direction, which is substantially perpendicular to the first surface 101s_1 of the substrate 101, for example, in the Z-direction. Upper surfaces of the separation structures 90 may be substantially coplanar with an upper surface of the gate capping layer 166, and upper ends of the separation structures 90 may be disposed in substantially the same height as an upper end of the gate capping layer 166, but the present inventive concept is not limited thereto. Lower ends of the separation structures 90 may be at a lower level than a level of a lower end of the source/drain regions 150.

In example embodiments of the present inventive concept, the separation structures 90 may have inclined side surfaces in which a width of a lower portion is narrower than a width of an upper portion depending on the aspect ratio, but the present inventive concept is not limited thereto. The lower portions of the separation structures 90 may have a flat surface. However, the present inventive concept is not limited thereto. For example, the lower portions of the separation structures 90 may have a convex shape or a pointed shape facing the substrate 101, but the present inventive concept is not limited thereto.

A first width w1 of an upper surface of the separation structure 91 of the cell region CR in the X-direction may be larger than a maximum horizontal width of the gate electrode 165 in the X-direction. A second width w2 of an upper surface of the separation structure 93 of the connection region CNR in the X-direction may be larger than a maximum horizontal width of the dummy gate electrode 265 in the X-direction. In addition, the second width w2 may be larger than the first width w1. The second width w2 may be about 5 nm or more, for example, about 5 nm to about 20 nm, about 5 nm to about 10 nm, or about 5 nm to about 8 nm.

The separation structures 90 may include an insulating material, and may include, for example, at least one of SiO, SiN, SiCN, SiOC, SiON, and/or SiOCN.

The through-electrode structure 80 may include a through-electrode 88 and an insulating spacer 82 at least partially surrounding a side surface of the through-electrode 88. The insulating spacer 82 may include, for example, silicon oxide. Accordingly, the insulating spacer 82 may provide separation between the through-electrode 88 and the substrate 101, and may provide separation between the through-electrode 88 and the first to third insulating structures 46, 56 and 66. The through-electrode 88 may include a pillar pattern 84 and a conductive barrier layer 86 at least partially surrounding a side surface of the pillar pattern 84. The pillar pattern 84 may include copper (Cu), but an embodiment of the present inventive concept is not limited thereto, and the pillar pattern 84 may include other conductive materials.

Referring to FIG. 2C, an outer surface of at least one of the first to third lower interlayer insulating layers 191, 193 and 195 and the first to third intermetallic insulating layers 50, 60 and 70 may be recessed in a direction away from the center of the through-electrode structure 80 in the first direction, for example, in the X-direction. For example, outer surfaces of the third lower interlayer insulating layer 195 and the first to third intermetallic insulating layers 50, 60 and 70 may have a concave shape recessed by the insulating spacer 82 of the through-electrode structure 80. For example, the insulating spacer 82 may fill the recessed portions of the third lower interlayer insulating layer 195 and the first to third intermetallic insulating layers 50, 60 and 70.

The through-electrode structure 80 may fill the through-region THR of the connection region CNR of the substrate 101 and may extend in the vertical direction. For example, the through-electrode structure 80 may penetrate through the first surface 101s_1 of the substrate 101 and the first to third insulating structures 46, 56 and 66 and may be in contact with a lower surface of a connection portion of the upper connection pattern UC. Additionally, the through-electrode structure 80 may penetrate through the second surface 101s_2 of the substrate 101 and the backside insulating layer 97 and may be in contact with an upper surface of the first conductive layer 99a of the backside conductive pattern 99.

At least a portion of the side surface of the through-electrode structure 80 may be in contact with at least a portion of a side portion of the first separation structure 93_1 in the Y-direction. Accordingly, the first separation structures 93_1 may be spaced apart from each other in the Y-direction by the through-electrode structure 80.

At least a portion of the side surface of the through-electrode structure 80 may be in contact with at least portions of side portions of the first source/drain regions 150_1 in the X-direction.

Accordingly, in a plan view, the first separation structure 93_1 may have a shape recessed in a direction away from the center of the through-electrode structure 80, and the first source/drain regions 150_1 may also have a shape recessed in a direction away from the center of the through-electrode structure 80.

The through-electrode structure 80 may have a tapering structure. For example, a horizontal width of the through-electrode structure 80 in the X-direction may decrease as the through-electrode structure 80 moves away from the upper connection pattern UC and approaches the backside conductive pattern 99.

When referring to FIGS. 1B and 2A together, a third width w3 of the upper surface of the through-electrode structure 80 in the X-direction may be larger than each of the first width w1 and the second width w2. The third width w3 may be about 1 um or more, for example, about 1 um to about 10 um, about 1 um to about 8 um, or about 1 um to about 6 um.

A lower end of the separation structure 93 of the connection region CNR may be disposed between a lower end of the first source/drain region 150_1 and a lower end of the through-electrode structure 80.

According to an example embodiment of the present inventive concept, a substantially identical environment may be implemented in the cell region CR and connection region CNR (or dummy region) that are adjacent to each other on the substrate 101, thereby minimizing the influence of the circuit elements of the cell region CR by the through-electrode structure 80 that is disposed in the connection region CNR. For example, a plurality of structures spaced apart from each other in the connection region CNR in the first direction (e.g., X-direction) and extending in the second direction (e.g., Y-direction), intersecting the first direction, may be arranged to provide the connection region CNR having substantially the same environment as the cell region CR. In this embodiment, the plurality of structures may be the separation structures 90. Accordingly, the influence of the through-electrode structure 80 formed in the connection region CNR on the circuit elements of the cell region CR may be minimized.

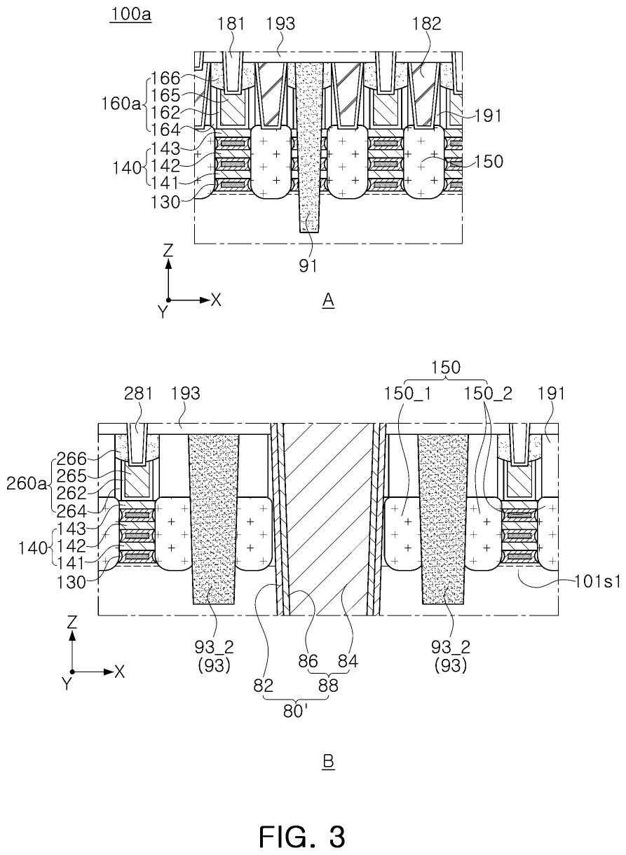

FIG. 3 is a partial enlarged view illustrating a semiconductor device according to example embodiments of the present inventive concept.

Referring to FIG. 3, a semiconductor device 100a may further include a channel structure 140 including a plurality of channel layers 141, 142 and 143 perpendicular to each other and spaced apart from each other on a first surface 101s1 of a substrate 101, and internal spacer layers 130 arranged in parallel with a gate electrode layer 165 that is between a plurality of channel layers 141, 142 and 143.

The semiconductor device 100a may include transistors with gate-all-around structure in which gate electrode layers 165 and 265 are disposed between the substrate 101 and the channel layers 141, 142 and 143 and between the neighboring nano-sheet-shaped channel layers 141, 142 and 143.

For example, the semiconductor device 100a may include transistors of a Multi Bridge Channel FET (MBCFETTM) structure formed by the channel layers 141, 142 and 143, source/drain regions 150, and gate structures 160 and 260.

The plurality of channel layers 141, 142 and 143 may be arranged in two or more on the substrate 101 to be spaced apart from each other in a direction that is perpendicular to the first surface 101s1 of the substrate 101, for example, in the Z-direction. The channel layers 141, 142 and 143 may be connected to the source/drain regions 150 and may be spaced apart from the first surfaces 101s1 of the substrate 101. The channel layers 141, 142 and 143 may have a width identical to or similar to a width of an active fin in the Y-direction, and may have a width identical to or similar to widths of gate structures 160a and 260a in the X-direction. However, according to example embodiments of the present inventive concept, the channel layers 141, 142 and 143 may have a decreased width so that side surfaces thereof are disposed below the gate structures 160 and 260 in the X-direction.

The plurality of channel layers 141, 142 and 143 may be made of a semiconductor material, and may include, for example, at least one of silicon (Si), silicon germanium (SiGe), and/or germanium (Ge). For example, the channel layers 141, 142 and 143 may be formed of the same material as a material of the substrate 101. The number and shape of the channel layers 141, 142 and 143 included in one channel structure may be variously changed in example embodiments of the present inventive concept.

The internal spacer layers 130 may be arranged to be parallel to the gate electrode layer 165 between the plurality of channel layers 141, 142 and 143. For example, the internal spacer layers 130 may be disposed between neighboring channel layers 141, 142, and 143. The gate electrode layer 165 may be electrically spaced apart from the source/drain regions 150 by the internal spacer layers 130. The internal spacer layers 130 may have a flat side facing the gate electrode layer 165 or may have a convexly rounded shape inward toward the gate electrode layer 165. For example, the internal spacer layers 130 may be formed of oxide, nitride, and oxynitride, and in particular, may be formed of a low dielectric constant film.

In example embodiments of the present inventive concept, the semiconductor device 100a of the MBCFETTM structure may be disposed in one region of the semiconductor device described above with reference to FIGS. 1A to 2C. Additionally, in example embodiments of the present inventive concept, the semiconductor device may also include a vertical field effect transistor (vertical FET) in which an active region, which extends perpendicular to the first surface 101s1 of the substrate 101, and a gate structure surrounding the active region are disposed.

In an example embodiment of the present inventive concept, a width of an upper surface of a through-electrode structure 80′ in the X-direction may be about 2 um or more, for example, about 2 um to about 6 um, or about 2 um to about 4 um.

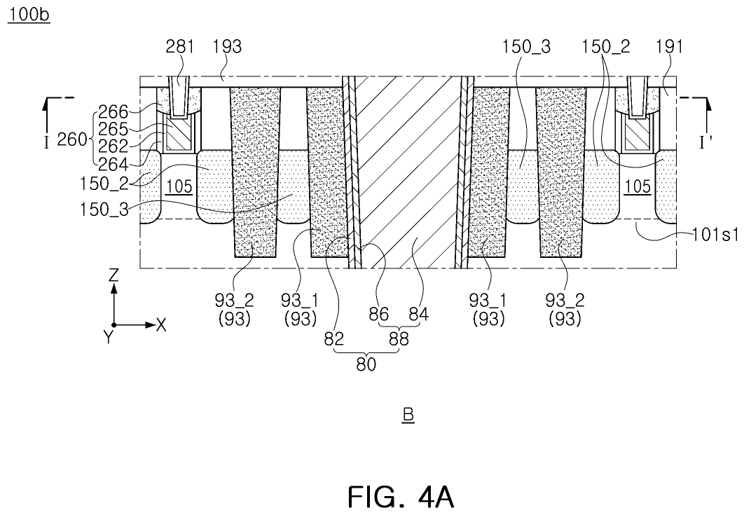

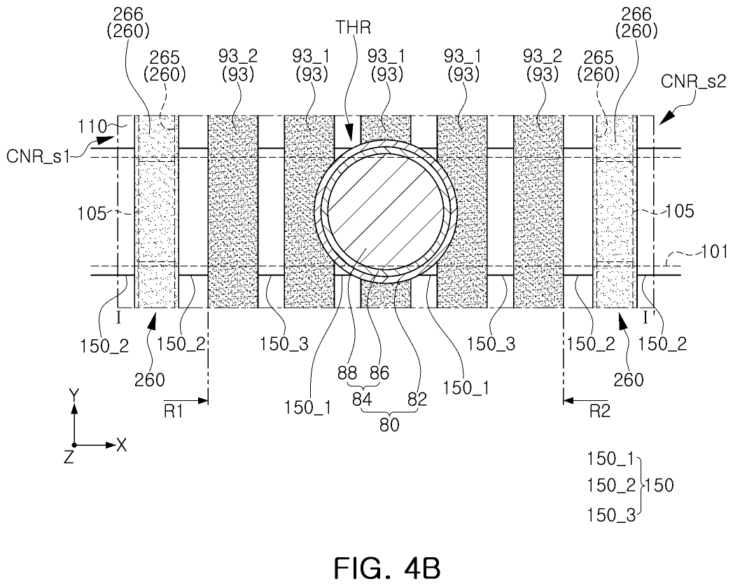

FIG. 4A is a partial enlarged view illustrating a semiconductor device according to example embodiments of the present inventive concept. FIG. 4B is a plan view of a semiconductor device according to an example embodiment of the present inventive concept. FIG. 4B is a plan view taken along line II′ of FIG. 4A.

Referring to FIGS. 4A and 4B, a semiconductor device 100b may be identical to or similar to that described with reference to FIGS. 1A to 3 except that the first separation structure 93_1 may have a recessed shape in a direction away from the center of the through-electrode structure 80 in a first direction, for example, the X-direction.

For example, a portion of an outer surface of the through-electrode structure 80 in the first direction, for example, the X-direction, may be in contact with at least a portion of a side surface of the first separation structure 93_1.

In an example embodiment of the present inventive concept, source/drain regions 150 may further include third source/drain regions 150_3 between a first source/drain region 150_1 and a second source/drain region 150_2. For example, the third source/drain regions 150_3 may be a source/drain region disposed between a first region R1 and a through-region THR, and between a second region R2 and the through-region THR. Referring to FIG. 4B, in each of a region between the first region R1 and the through-region THR and a region between the second region R2 and the through-region THR, the third source/drain region 150_3 is illustrated as one component, but the present inventive concept is not limited thereto. For example, the third source/drain regions 150_3 may be arranged in plural in each of the regions.

Accordingly, a second separation structure 93_2 of an example embodiment may be defined as a separation structure disposed between the first source/drain region 150_1 and the second source/drain region 150_2 that are adjacent to each other, between the second source/drain region 150_2 and the third source/drain region 150_3 that are adjacent to each other, and between the third source/drain regions 150_3 that are adjacent to each other.

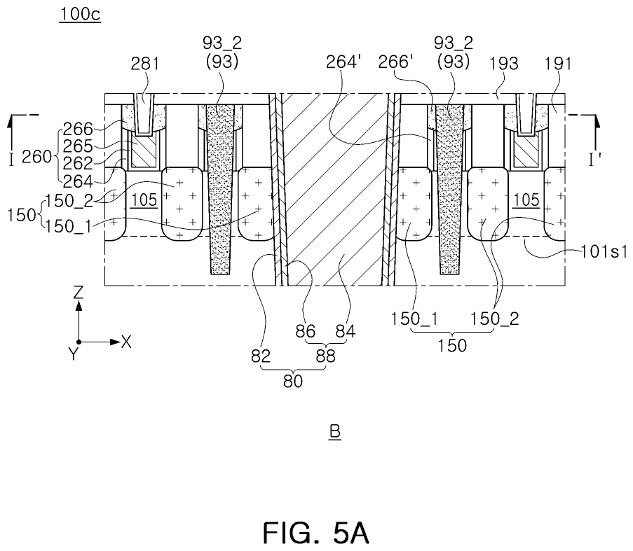

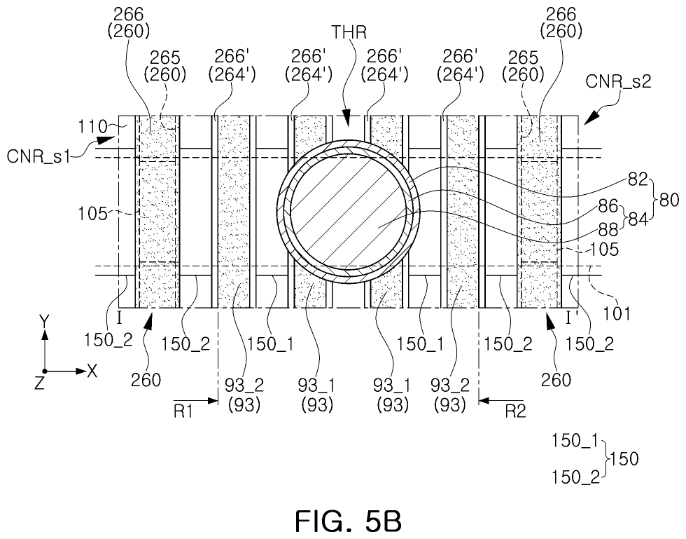

FIG. 5A is a partial enlarged view illustrating a semiconductor device according to example embodiments of the present inventive concept. FIG. 5B is a plan view of a semiconductor device according to an example embodiment of the present inventive concept. FIG. 5B is a plan view taken along line II′ of FIG. 5A.

Referring to FIGS. 5A and 5B, a semiconductor device 100c may be identical to or similar to that described with reference to FIGS. 1A to 4B except that a separation structure 93 includes at least one insulating pattern on a side surface of an upper region thereof.

The at least one insulating pattern may include a first insulating pattern 264′ and a second insulating pattern 266′ on the first insulating pattern 264′. The first insulating pattern 264′ may be a portion where the separation structure 93 is disposed on a side surface of an upper region thereof, and the second insulating pattern 266′ may be a portion disposed on the first insulating pattern 264′. An upper surface of the second insulating pattern 266′ may be substantially coplanar with an upper surface of the separation structure 93.

The first insulating pattern 264′ may include the same material as a dummy gate spacer 264 of a dummy gate structure 260, and the second insulating pattern 266′ may include the same material as a dummy gate capping layer 266 of the dummy gate structure 260.

The first insulating pattern 264′ and the separation structure 93 may include different materials from each other. For example, the first insulating pattern 264′ may include SiO, and the separation structure 93 may include SiN, but the present inventive concept is not limited thereto. The second insulating pattern 266′ and the separation structure 93 may include different materials from each other. For example, the second insulating pattern 266′ may include SiN, and the separation structure 93′ may include SiO or SiOC, but the present inventive concept is not limited thereto.

The first and second insulating patterns 264′ and 266′ may be in contact with at least a portion of a side surface of the through-electrode structure 80.

FIG. 6A is a partial enlarged view illustrating a semiconductor device according to example embodiments of the present inventive concept. FIG. 6B is a plan view of a semiconductor device according to an example embodiment of the present inventive concept. FIG. 6B is a plan view taken along line I-I′ of FIG. 6A.

Referring to FIGS. 6A and 6B, a semiconductor device 100d may be identical to or similar to that described in FIGS. 1A to 5B except that the semiconductor device 100d further includes a separation pattern 282P disposed on at least one side of a separation structure 93. For example, the separation pattern 282P may be disposed on the first and second source/drain regions 150_1 and 150_2 such that the separation pattern 282P penetrates the first and second source/drain regions 150_1 and 150_2. For example, a lower end of the separation pattern 282P recesses upper regions of the first and second source/drain regions 150_1 and 150_2.

Referring to FIGS. 6A and 6B, in an example embodiment of the present inventive concept, the semiconductor device 100d may further include a second contact plug 282 electrically connected to a second source/drain region 150_2. An upper end and a lower end of the separation pattern 282P may be on substantially the same levels as an upper end and a lower end of the second contact plug 282, respectively. The lower end of the separation pattern 282P may be disposed between an upper end of the second source/drain region 150_2 and a lower end of the separation structure 93.

The separation pattern 282P may be in contact with at least a portion of a side surface of the through-electrode structure 80. Accordingly, a portion of the separation pattern 282P may have a shape that is recessed in a direction away from the center of the through-electrode structure 80 in the first direction (e.g., X-direction) and/or the second direction (e.g., Y-direction).

The separation pattern 282P may include an insulating material, and may include, for example, at least one of SiO, SiN, SiCN, SiOC, SiON, and SiOCN. The separation pattern 282P and the separation structure 93 may include the same material, but boundaries thereof may be distinct from each other.

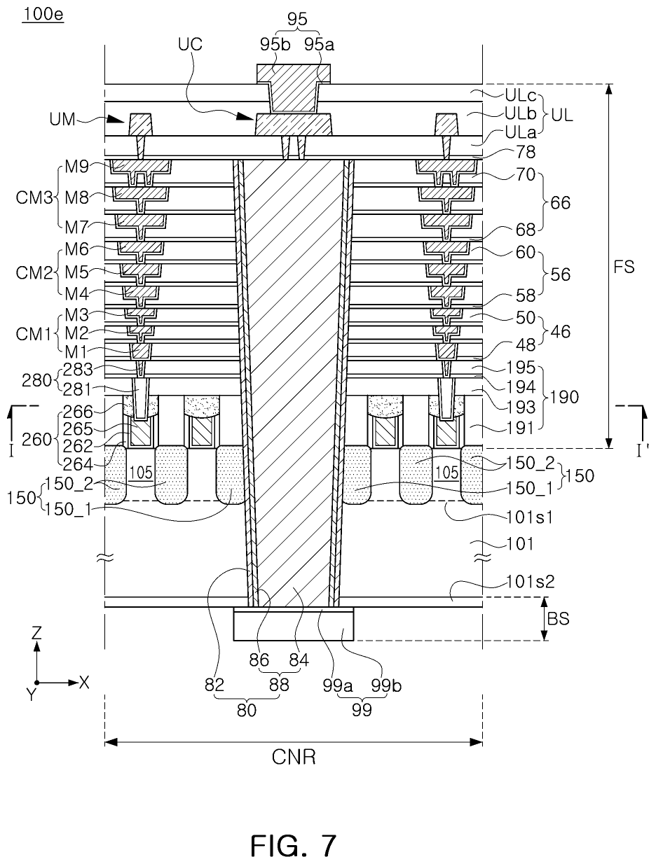

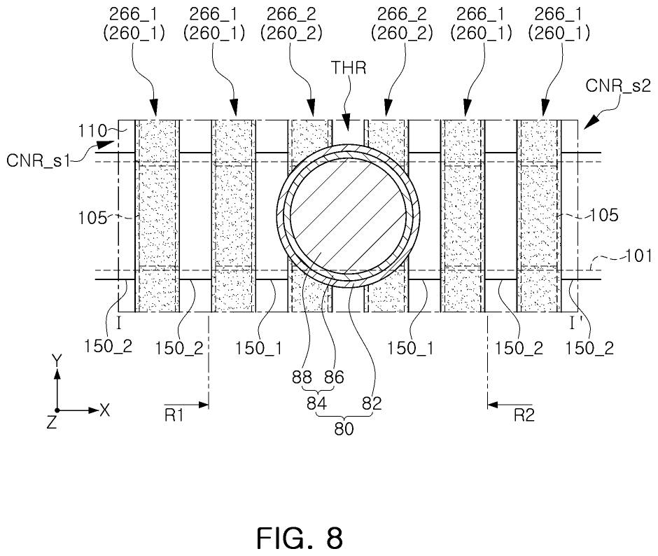

FIG. 7 is a cross-sectional view illustrating a semiconductor device according to an example embodiment of the present inventive concept. FIG. 8 is a plan view of a semiconductor device according to an example embodiment of the present inventive concept. FIG. 8 is a plan view taken along cutting line II′ of FIG. 7.

Referring to FIGS. 7 and 8, a semiconductor device 100e may be identical to or similar to that described with reference to FIGS. 1A to 6B except that the semiconductor device 100e further includes a gate structure between a first region RI and a second region R2. For example, a cell region CR of the semiconductor device 100e may have substantially the same characteristics as the cell region CR of the semiconductor device 100a described with reference to FIG. 1A.

In an example embodiment of the present inventive concept, gate structures of the first region R1 and the second region R2 may be defined as a first gate structure 260_1, and a gate structure between the first region R1 and the second region R2 may be defined as a second gate structure 260_2.

Since the first gate structure 260_1 of this example embodiment may have substantially the same characteristics as the gate structure 260 described with reference to FIGS. 1A to 2C, detailed explanation thereof will be omitted.

Referring to FIGS. 7 and 8, the second gate structure 260_2 may be defined as a gate structure in which at least a portion of the gate structure 260 has a portion vertically overlapping the through-region THR. From another perspective, the semiconductor device 100e of an example embodiment of the present inventive concept might not include the separation structure 90 described with reference to FIGS. 1A to 2C. Accordingly, the second gate structure 260_2 may be in contact with at least a portion of a side surface of a through-electrode structure 80.

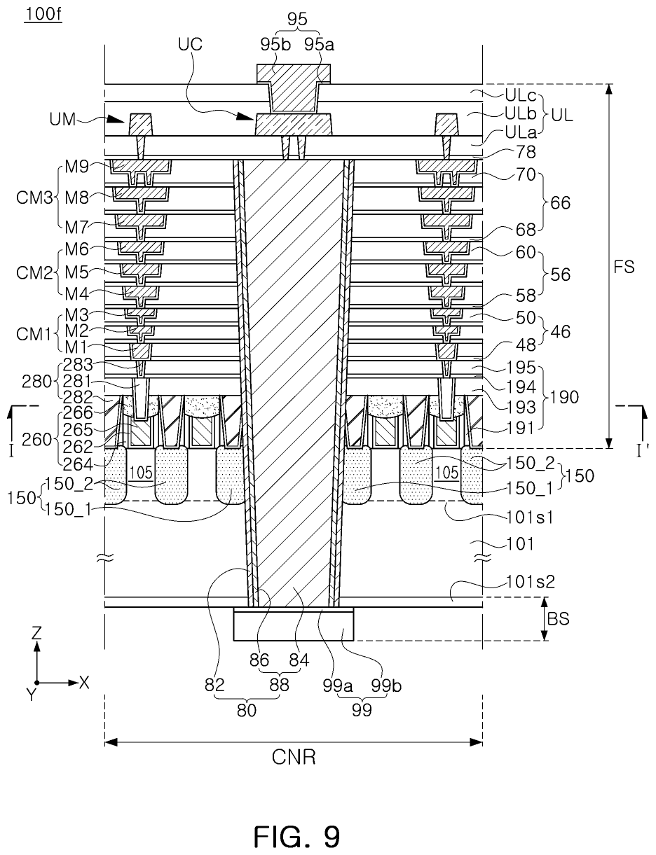

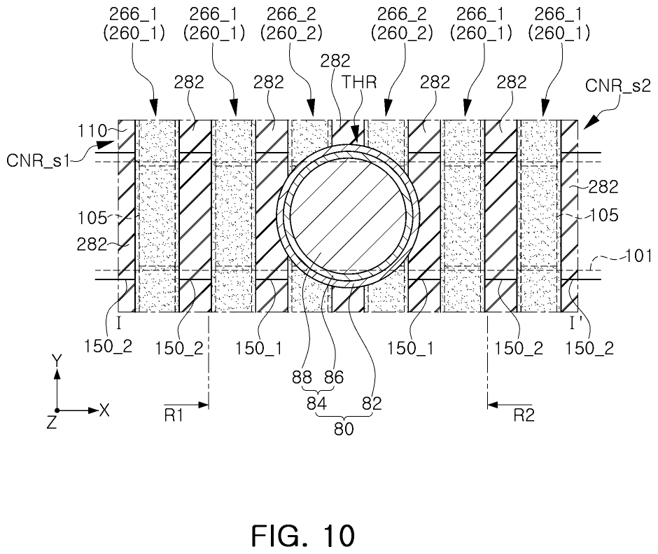

FIG. 9 is a cross-sectional view illustrating a semiconductor device according to an example embodiment of the present inventive concept. FIG. 10 is a plan view of a semiconductor device according to an example embodiment of the present inventive concept. FIG. 10 is a plan view taken along cutting line II′ of FIG. 9.

Referring to FIGS. 9 and 10, a semiconductor device 100f may be identical to or similar to that described with reference to FIGS. 1A to 8, except that the semiconductor device 100f further includes contact plugs 282 in a connection region CNR. Referring to FIGS. 9 and 10, especially compared to FIGS. 7 and 8, the semiconductor device 100f further include contact plugs 282 in contact with an upper surface of a source/drain region 150 on two sides (e.g., opposing sides) of gate structures 260.

The contact plugs 282 may be spaced apart from each other in the first direction (e.g., X-direction), and the gate structures 260 may be alternately arranged with the contact plugs 282 in the first direction. The contact plugs 282 may extend in the second direction (e.g., Y-direction). For example, the contact plugs 282 may include a portion disposed between first gate structures 260_1 that are adjacent to each other, in the first region R1 and the second region R2. The contact plugs 282 may further include a portion disposed between the first and second gate structures 260_1 and 260_2 that are adjacent to each other and a portion disposed between the second gate structures 260_2 that are adjacent to each other, between the first region R1 and the second region R2. At least some of the contact plugs 282 that are disposed between the first region R1 and the second region R2 may be in contact with at least a portion of side surfaces of the through-electrode structures 80.

As described with reference to FIGS. 1A to 2C, in the present inventive concept, a plurality of structures spaced apart from each other in the connection region CNR in the first direction (e.g., X-direction) and extending in the second direction (e.g., Y-direction), intersecting the first direction, may disposed to provide the connection region CNR, which has substantially the same environment as the cell region CR. In this example embodiment of the present inventive concept, the plurality of structures may be contact plugs 282. Accordingly, the influence of the through-electrode structure 80 formed in the connection region CNR on the circuit elements of the cell region CR may be minimized.

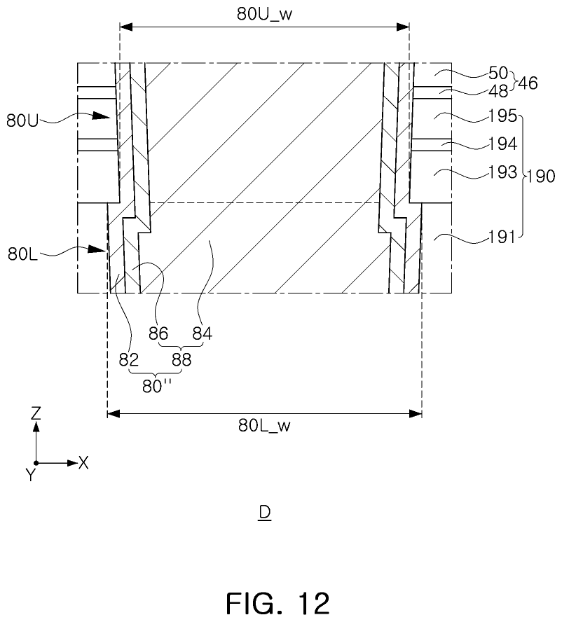

FIG. 11 is a cross-sectional view illustrating a semiconductor device according to an example embodiment of the present inventive concept. FIG. 12 is a partial enlarged view illustrating a semiconductor device according to example embodiments of the present inventive concept. FIG. 12 is a partial enlarged view of region ‘D’ in FIG. 11.

Referring to FIGS. 11 and 12, a semiconductor device 100g may be identical to or similar to that described with reference to FIGS. 1A to 10 except that a side surface of the through-electrode structure 80″ has a step portion.

The through-electrode structure 80″ may be defined as having a first portion 80L and a second portion 80U disposed on the first portion 80L. The first portion 80L and the second portion 80U may be defined based on an upper surface of a first lower interlayer insulating layer 191 and/or a lower surface of a second lower interlayer insulating layer 193. For example, the first portion 80L may be a portion that is disposed below an upper surface of the first lower interlayer insulating layer 191, and the second portion 80U may be a portion that is disposed above the upper surface of the first lower interlayer insulating layer 191. Accordingly, an upper surface of the first portion 80L may be substantially coplanar with upper surfaces of the gate structures 260, and a lower surface of the second portion 80U may be substantially coplanar with the upper surfaces of the gate structures 260.

A horizontal width 80L_w of the upper surface of the first portion 80L may be larger than a horizontal width 80U_w of the lower surface of the second portion 80U. Accordingly, a side surface of the first portion 80L and a side surface of the second portion 80U may form a step portion. For example, the side surface of the second portion 80U may be formed on the upper surface of the first portion 80L such that at least a portion of the upper surface of the first portion 80L is exposed thereby forming a step portion in a side surface of the through electrode structure 80″.

Accordingly, an insulating spacer 82, a conductive barrier layer 86 and a pillar pattern 88 may have a shape bent in a direction away from the center of the through-electrode structure 80″ near boundaries of the first and second lower interlayer insulating layers 191 and 193.

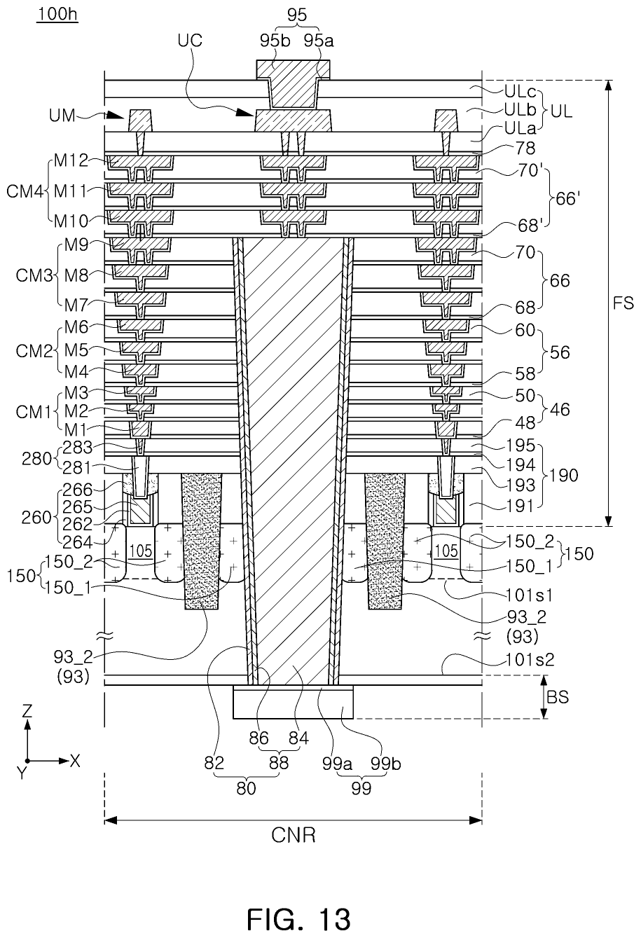

FIG. 13 is a cross-sectional view illustrating a semiconductor device according to an example embodiment of the present inventive concept.

Referring to FIG. 13, a semiconductor device 100h may be identical to or similar to that described with reference to FIGS. 1A to 12 except that the semiconductor device 100h further includes a fourth circuit interconnection structure CM4 on a through-electrode structure 80.

Referring to FIG. 13, especially compared to FIG. 1B, a front structure FS may further include a fourth circuit interconnection structure CM4 that is disposed between a third circuit interconnection structure CM3 and an upper circuit interconnection pattern UM, and a fourth insulating structure 66′ that is disposed between a third insulating structure 66 and an upper insulating structure UL.

The fourth circuit interconnection structure CM4 may be disposed within the fourth insulating structure 66′ and may include a plurality of circuit interconnection patterns disposed on different levels from each other. For example, the fourth circuit interconnection structure CM4 may include tenth, eleventh and twelfth circuit interconnection patterns M10, M11 and M12 disposed on different levels from each other. The tenth, eleventh and twelfth circuit interconnection patterns M10, M11 and M12 may penetrate through one fourth insulating barrier layer 68′ and one third intermetallic insulating layer 70′ which are sequentially stacked.

Each of the fourth circuit interconnection structure CM4 and the fourth insulating structure 66′ may have characteristics identical to or similar to each of the first to third circuit interconnection structures CM1, CM2 and CM3 and the first to third insulating structures 46, 56 and 66 described with reference to FIGS. 1A to 2C. Accordingly, the description of the fourth circuit interconnection structure CM4 and the fourth insulating structure 66′ according to FIG. 12 may only be described with regard to differences from that described with reference to FIGS. 1A to 2C.

Referring to FIG. 13, the tenth, eleventh and twelfth circuit interconnection patterns M10, M11 and M12 may be disposed between an upper connection pattern UC and a through-electrode structure 80. For example, a portion of the tenth circuit interconnection pattern M10 may be formed on the through-electrode structure 80 and may be electrically connected to the through-electrode structure 80. Similarly, a portion of the eleventh circuit interconnection pattern M11 may be disposed on the portion of the tenth circuit interconnection pattern M10 and may be electrically connected to the through-electrode structure 80 through the tenth circuit interconnection pattern M10, and a portion of the twelfth circuit interconnection pattern M12 may be disposed on the portion of the eleventh circuit interconnection pattern M11 and may be electrically connected to the through-electrode structure 80 through the eleventh circuit interconnection pattern M11 and the tenth circuit interconnection pattern M10. Accordingly, the upper connection pattern UC and the through-electrode structure 80 may be electrically connected through the tenth, eleventh, and twelfth circuit interconnection patterns M10, M11 and M12. In this example embodiment, the upper connection pattern UC and the tenth, eleventh, and twelfth circuit interconnection patterns M10, M11 and M12 may be referred to as front conductive patterns.

Each of the tenth, eleventh, and twelfth circuit interconnection patterns M10, M11 and M12 are illustrated as being spaced apart from each other on the ninth circuit interconnection patterns M9 and the through-electrode structure 80, but the present inventive concept is not limited thereto. For example, an interconnection portion of the tenth circuit interconnection pattern M10 may extend in the first direction (e.g., X-direction) on the ninth circuit interconnection patterns M9 and the through-electrode structure 80, and may electrically connect the ninth circuit interconnection patterns M9 and the through-electrode structure 80. Accordingly, the ninth circuit interconnection patterns M9 and the through-electrode structure 80 may be electrically connected to each other by the interconnection portion of the tenth circuit interconnection pattern M10.

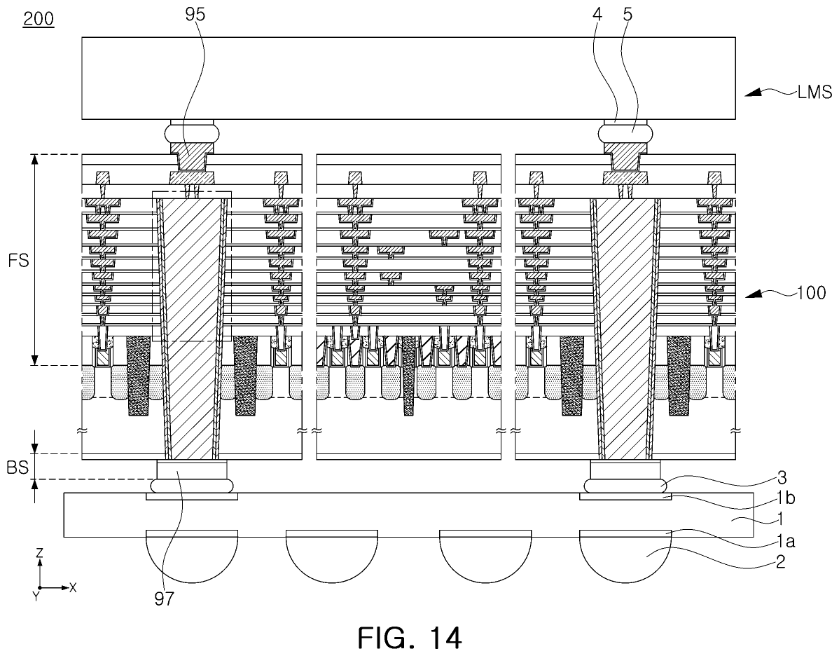

Next, a semiconductor package including the semiconductor device described above will be described with reference to FIG. 14.

Referring to FIG. 14, a semiconductor package 200 may include a base substrate 1, a first semiconductor device 100, a second semiconductor device LMS, first connection patterns 3, second connection patterns 5. The first semiconductor device 100 may be disposed on the base substrate 1. The second semiconductor device LMS may be disposed on the first semiconductor device 100. The first connection patterns 3 may electrically connect the base substrate 1 and the first semiconductor device 100 to each other, and may be disposed between the base substrate 1 and the first semiconductor device 100. The second connection patterns 5 may electrically connect the first semiconductor device 100 and the second semiconductor device LMS to each other, and may be disposed between the first semiconductor device 100 and the second semiconductor device LMS. The semiconductor package 200 may further include solder balls 2 that are disposed below the base substrate 1.

The first semiconductor device 100 may include microprocessors such as a central processor unit (CPU), a graphics processor unit (GPU) and an application processor (AP), or logic chips such as a field programmable gate array (FPGA) and an application-specific IC (ASIC).

The second semiconductor device LMS may include at least one of a logic chip, a memory chip, and a sensor chip. For example, the second semiconductor device LMS may include microprocessors such as a central processor unit (CPU), a graphics processor unit (GPU) and an application processor (AP), logic chips such as a field programmable gate array (FPGA) and an application-specific IC (ASIC), or a memory chip. The memory chip may be a volatile memory chip or a non-volatile memory chip. For example, the volatile memory chip may include a dynamic random access memory (DRAM), a static RAM (SRAM), a thyristor RAM (TRAM), a zero capacitor RAM (ZRAM), or a twin transistor RAM (TTRAM). Additionally, the non-volatile memory chip may include, for example, a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory or an insulation resistance change memory.

The base substrate 1 may be a printed circuit board or an interposer board. The base substrate 1 may include pads 1a, which are electrically connected to the solder balls 2, and pads 1b, which are electrically connected to the first connection patterns 3.

The second semiconductor device LMS may further include pads 4 electrically connected to the second connection patterns 5.

The first semiconductor device 100 may be a semiconductor device according to any one of the example embodiments described with reference to FIGS. 1 to 13.

In the first semiconductor device 100, a circuit element and a front structure FS may face a second semiconductor device LMS. Accordingly, in the first semiconductor device 100, a backside conductive pattern 97 may be electrically connected to the first connection patterns 3, and the front pads 95 may be electrically connected to the second connection patterns 5. According to an example embodiment of the present inventive concept, the first semiconductor device 100 may further include a backside protective layer covering the backside conductive pattern 97 and having openings exposing a region in which the backside conductive pattern 97 and the first connection patterns 3 are in contact with each other.

According to an example embodiment of the present inventive concept, in the semiconductor package of the present invention, the circuit element and the front structure FS of the first semiconductor device 100 may face the base substrate 1. Accordingly, in the first semiconductor device 100, the backside conductive pattern 97 may be electrically connected to the second connection patterns 5, and the front pads 95 may be electrically connected to the first connection patterns 3.

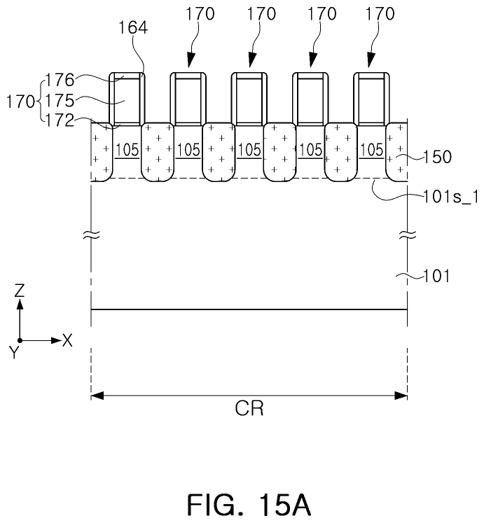

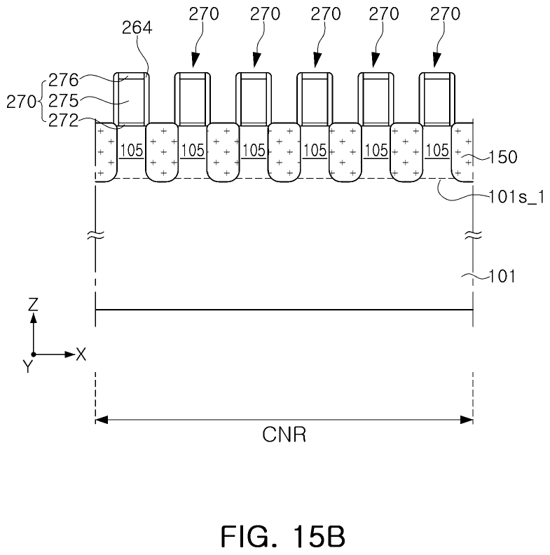

FIGS. 15A to 27B are vertical cross-sectional views illustrating a method of manufacturing a semiconductor device 100 according to an example embodiment of the present inventive concept. FIGS. 15A, 16A, 17A, 18A, 19A, 20A, 21A, 22A, 23A, 24A, 25A, 26A, and 27A are drawings corresponding to FIG. 1A, and FIGS. 15B, 16B, 17B, 18B, 19B, 20B, 21B, 22B, 23B, 24B, 25B, 26B and 27B may be drawings corresponding to FIG. 1B.

Referring to FIGS. 15A and 15B, sacrificial gate structures 170 and 270 and gate spacer layers 164 and 264 may be formed on an active structure including a substrate 101 and active regions 105, and source/drain regions 150 may be formed on the substrate 101 on two sides (e.g., opposing sides) of the sacrificial gate structures 170 and 270.

A portion of the substrate 101 may be removed so that the active regions 105 protrude from the first surface 101s1 of the substrate 101. The active structures including the substrate 101 and the active regions 105 may be formed in the form of a line extending in one direction, for example, the X-direction, and may be spaced apart from each other in the Y-direction. For example, the active regions 105 may extend in the Y-direction and may be spaced apart from each other in the X-direction. Device isolating layers 110 may be formed by filling an insulating material in a region from which the portion of the substrate 101 has been removed (see FIG. 2B).

Sacrificial gate structures 170 and 270 and gate spacer layers 164 and 264 may be formed on the active structure. The sacrificial gate structures 170 and 270 may be sacrificial structures formed in a region in which a gate dielectric layer 162 and a gate electrode 165 are disposed on upper portions of the active regions 105, as illustrated in FIGS. 1A and 1B through a subsequent process. The sacrificial gate structures 170 and 270 may include first and second sacrificial gate layers 172, 272, 175 and 275 and gate mask pattern layers 176 and 276 which are sequentially stacked on each other. The first and second sacrificial gate layers 172, 272, 175 and 275 may be patterned by using the gate mask pattern layers 176 and 276. The first and second sacrificial gate layers 172, 272, 175 and 275 may be an insulating layer and a conductive layer, respectively, but the present inventive concept is not limited thereto, and the first and second sacrificial gate layers 172, 272, 175 and 275 may be formed as a single layer. For example, the first sacrificial gate layers 172 and 272 may include silicon oxide, and the second sacrificial gate layers 175 and 275 may include polysilicon. The gate mask pattern layers 176 and 276 may include, for example, silicon oxide and/or silicon nitride. The sacrificial gate structures 170 and 270 may have a line shape extending in one direction by intersecting the active structures. For example, the sacrificial gate structures 170 and 270 may extend in the Y-direction and may be spaced apart from each other in the X-direction.

The gate spacer layers 164 and 264 may be formed on both sidewalls of the sacrificial gate structures 170 and 270. The gate spacer layers 164 and 264 may be formed by forming a film of uniform thickness along upper surfaces and side surfaces of the sacrificial gate structures 170 and 270 and the active structures, and then performing anisotropic etching. The gate spacer layers 164 and 264 may be formed of a low dielectric constant material, and may include, for example, at least one of SiO, SiN, SiCN, SiOC, SiON, and SiOCN.

A recessed region may be formed by removing an exposed substrate 101 between the sacrificial gate structures 170 and 270, and the source/drain regions 150 may be formed in the recess region. The source/drain regions 150 may be formed by performing an epitaxial growth process. The source/drain regions 150 may include impurities by in-situ doping, and may include a plurality of layers with different doping elements and/or different doping concentrations.

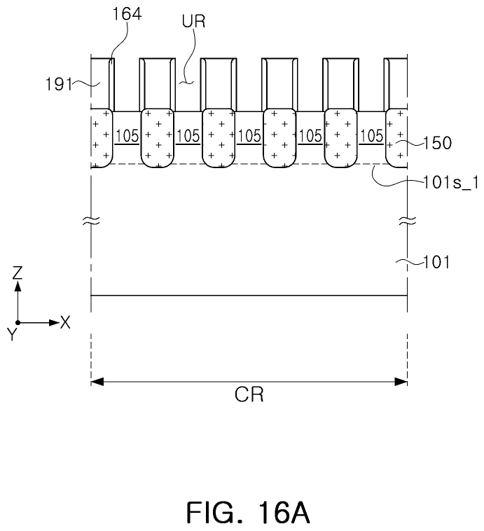

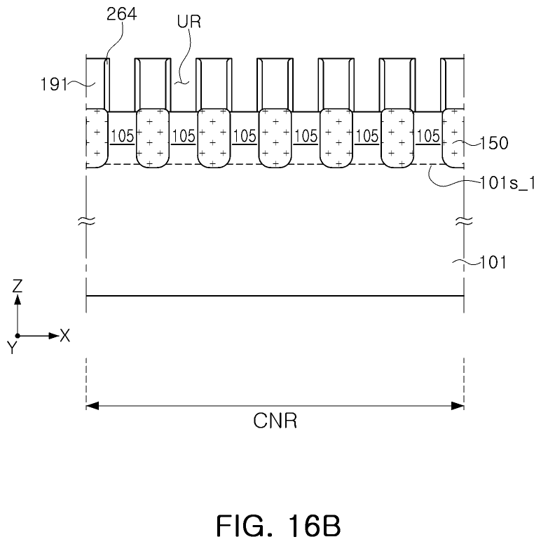

Referring to FIGS. 16A and 16B, a lower interlayer insulating layer 191 may be formed, and the sacrificial gate structures 170 may be removed to form an upper gap regions UR.

The lower interlayer insulating layer 191 may be formed by forming an insulating film covering the sacrificial gate structures 170 and 270 and the source/drain regions 150 and performing a flattening process.

The sacrificial gate structures 170 and 270 may be removed selectively with respect to the gate spacer layers 164 and 264 and the lower interlayer insulating layer 191.

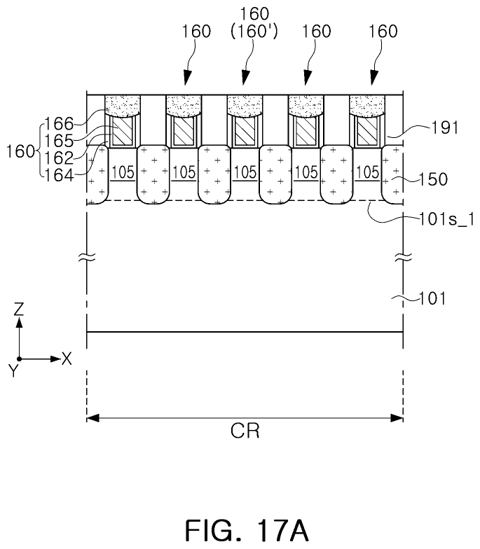

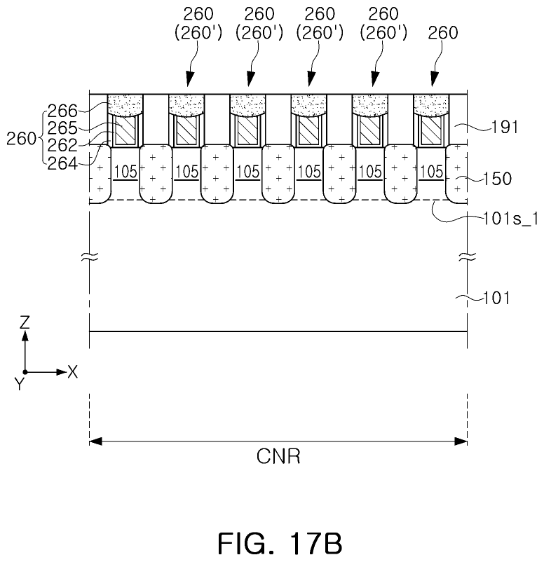

Referring to FIGS. 17A and 17B, gate structures 160 and 260 may be formed in an upper gap regions UR.

Gate dielectric layers 162 and 262 may be formed to conformally cover internal surfaces of the upper gap regions UR. The gate electrodes 165 and 265 may be formed to fill the upper gap regions UR and may then be removed by a predetermined depth from an upper portion in the upper gap regions UR. Gate capping layers 166 and 266 may be formed in a region in which the gate electrodes 165 and 265 have been removed from the upper gap regions UR. Accordingly, the gate structures 160 and 260 including the gate dielectric layers 162 and 262, the gate electrodes 165 and 265, the gate spacer layers 164 and 264 and the gate capping layers 166 and 266 may be formed.

At least one of the gate structures 160 may be partially removed through a subsequent process. This may be referred to as a gate structure 160′ to be removed. Similarly, at least one of the gate structures 260 may be partially or entirely removed through a subsequent process. This may be referred to as a gate structure 260′ to be removed.

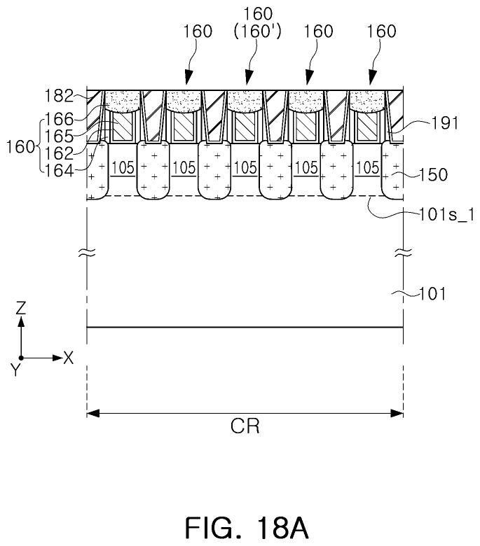

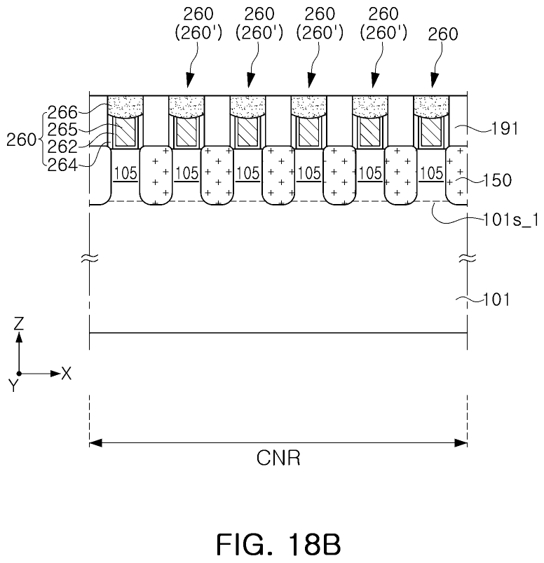

Referring to FIGS. 18A and 18B, contact plugs 182 electrically connected to the source/drain region 150 may be formed on two sides of the gate structures 160.

After forming a predetermined mask pattern covering upper portions of the gate structures 160 and the lower interlayer insulating layer 191, a contact hole recessing an upper region of the source/drain region 150 may be formed. Then, contact plugs 182 may be formed by filling the contact hole with a conductive material.

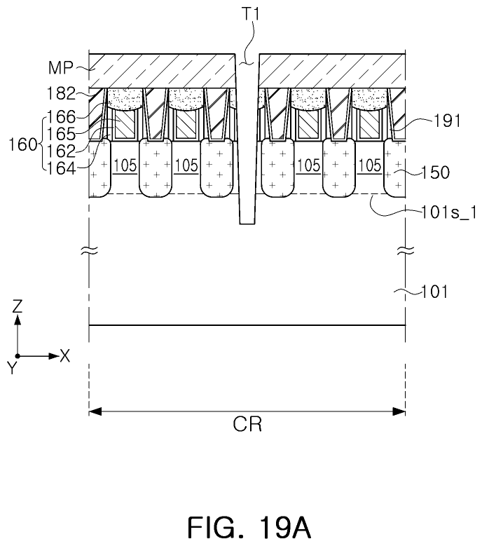

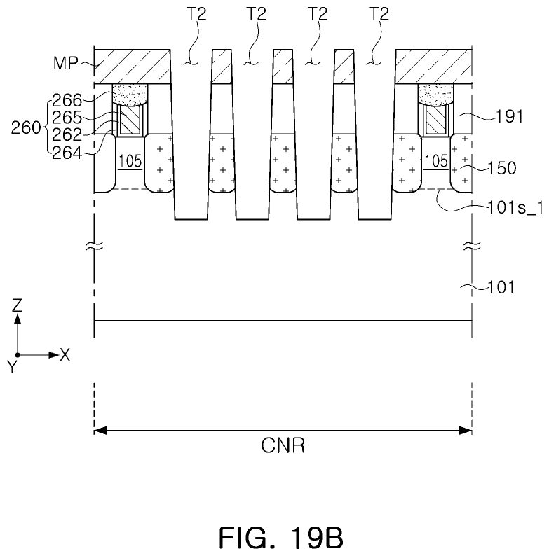

Referring to FIGS. 19A and 19B, a mask pattern layer MP may be formed on upper portions of the gate structures 160 and 260 and the lower insulating layer 191, and trenches T1 and T2, which penetrate through the gate structures 160′ and 260′ that are to be removed and which extend below a lower end of the source/drain region 150, may be formed.

At least a portion of the gate structure 160′ to be removed, for example, the gate electrode 165 including the conductive material, may be removed by the trench T1. Similarly, the gate structure 260′ to be removed, including the gate electrode 265 including the conductive material, may be removed by the trench T2.

A horizontal width of the trench T2 penetrating through the gate structure 260′, which is to be removed, may be larger than horizontal widths of each of the trenches T1 penetrating through the gate structure 160′, which is to be removed.

The mask pattern layer MP may include a compound including silicon. For example, the mask pattern layer MP may include TetraEthyl OrthoSilicate (TEOS).

The trenches T1 and T2 may intersect the active region 105 and extend in the second direction, for example, the Y-direction. The trenches T1 and T2 may have inclined side surfaces in which a width of a lower portion thereof is narrower than a width of an upper portion thereof depending on the aspect ratio. Lower portions of the trenches T1 and T2 may have a flat surface. However, the present inventive concept is not limited thereto. For example, the lower portions of the trenches T1 and T2 may have a convex shape or a pointed shape toward the substrate 101, but the present inventive concept is not limited thereto. A lower end of the trench T may be disposed to be lower than a lower end of the active region 105.

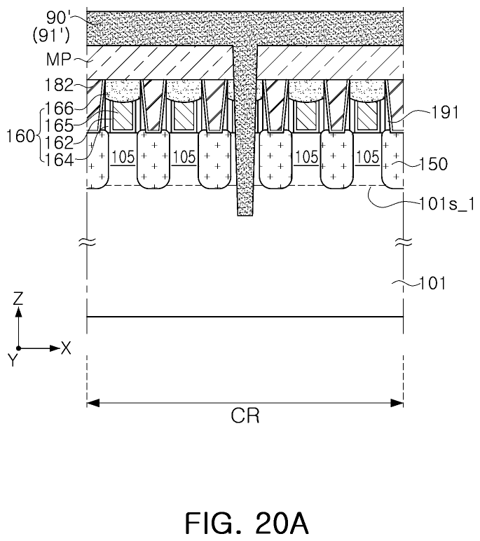

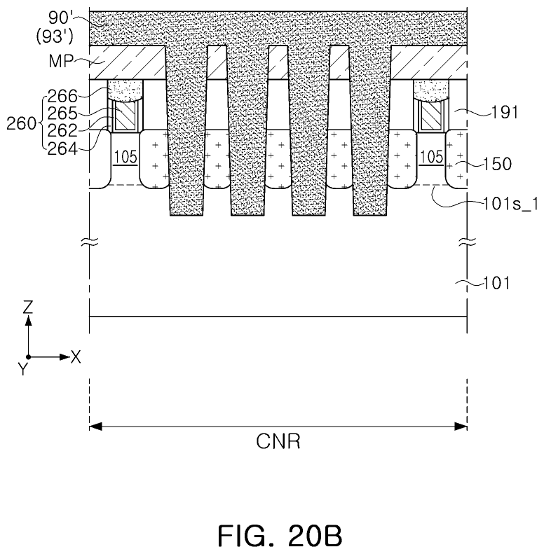

Referring to FIGS. 20A and 20B, a preliminary separation structure 90′ filling interiors of the trenches T1 and T2 and covering an upper portion of the mask pattern layer MP may be formed.

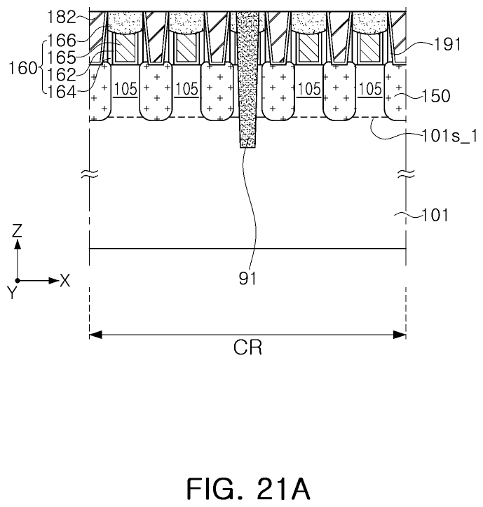

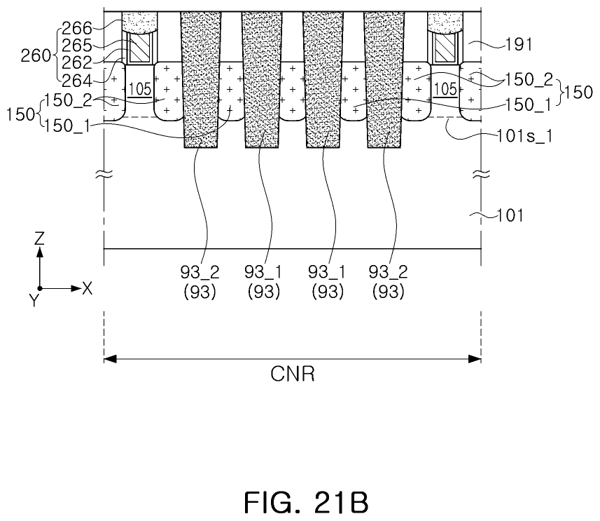

Referring to FIGS. 21A and 21B, through a Chemical Mechanical Polishing (CMP) process, the mask pattern layer MP and some regions of the preliminary separation structure 90′ may be removed to form separation structures 91 and 93.

By the CMP process, the preliminary separation structure 90′ and the mask pattern layer MP disposed on a level higher than a level of boundary surfaces between the mask pattern layer MP and the gate capping layers 166 and 266 may be removed.

The separation structure 93 may be referred to as a first separation structure 93_1 at least partially in contact with a side surface of a through-electrode structure 80, and a second separation structure 93_2 which is not in contact with the side surface of the through-electrode structure 80, through a subsequent process.

Similarly, the source/drain regions 150 may be referred to as first source/drain regions 150_1 at least partially in contact with the side surface of the through-electrode structure 80, and second source/drain regions 150_2 which are not in contact with the side surface of the through-electrode structure 80, through the subsequent process.

According to an example embodiment of the present inventive concept, contact plugs 182 and 282 and the separation structures 91 and 93 may be formed in different orders from each other. For example, after the separation structures 91 and 93 are first formed, the contact plugs 182 and 282 electrically connected to the source/drain region 150 may be formed on both sides of the gate structures 160 and 260.

In addition, referring to FIG. 6A again together with FIGS. 18A and 18B, the contact plugs 282 electrically connected to the source/drain region 150 may be formed on both sides of the gate structures 160 as well as on both sides of the gate structures 260.

In this case, before forming the separation structure 90, a separation pattern 282P between the gate structures 260 may be formed first.

In this case, a predetermined mask pattern layer may be formed on the gate structures 260 and the contact plugs 282 between the gate structures 260, and trenches penetrating through the predetermined mask pattern layer and the at least one contact plug 282 may be formed to expose at least a portion of an upper region of the source/drain region 150. By filling the trench with an insulating material, the separation pattern 282P may be formed (see FIG. 6A).

Then, in substantially the same manner as described with reference to FIGS. 19A to 21B, a separation structure 90 may be formed between the separation patterns 282P.

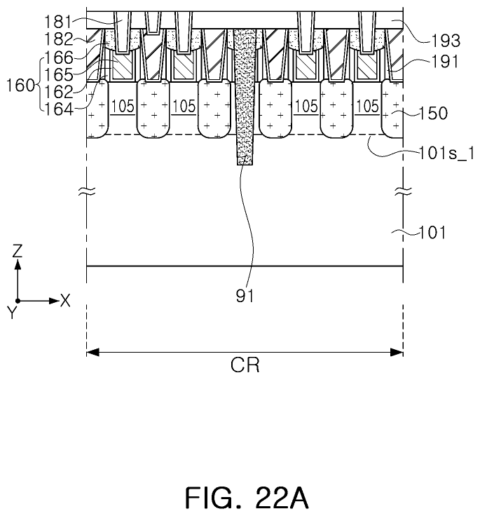

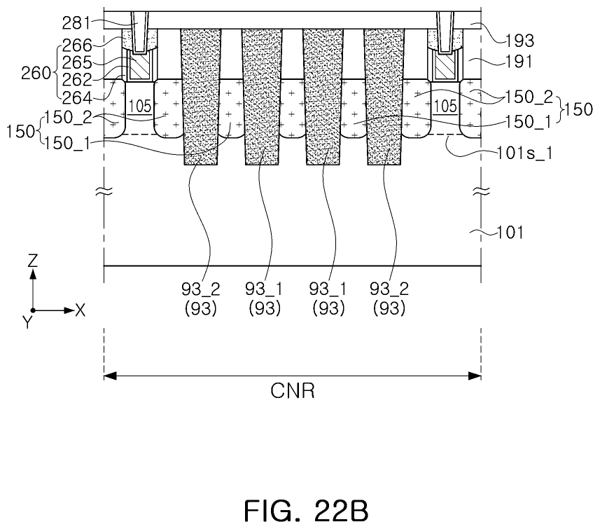

Referring to FIGS. 22A and 22B, a lower interlayer insulating layer 193, which cover upper surfaces of the gate structures 160 and 260, the contact plugs 182 and the separation structures 91 and 93, and contact plugs 181 and 281, which penetrate through the lower interlayer insulating layer 193 and are electrically connected to the gate structures 160 and 260 may be formed.

Since forming the contact plugs 181 and 281 may be substantially the same as forming the contact plugs 182 and 282 described with reference to FIGS. 17A and 17B, detailed descriptions thereof will be omitted.

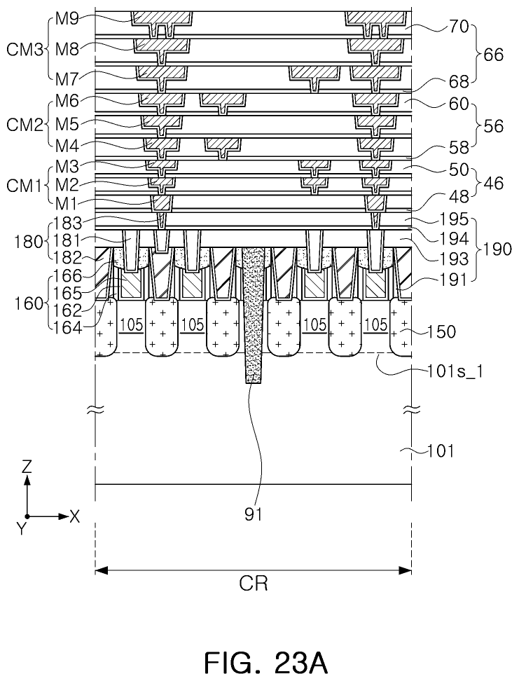

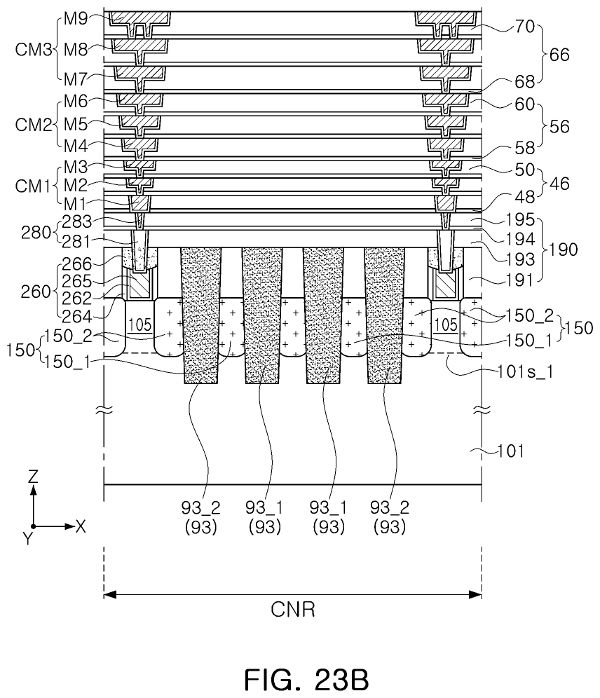

Referring to FIGS. 23A and 23B, a lower insulating barrier layer 194 may be formed on the lower interlayer insulating layer 193, and a lower interlayer insulating layer 195 and contact plugs 183 and 283 may be formed on the lower interlayer insulating layer 193. Insulating structures 46, 56 and 66 and circuit interconnection patterns CM1, CM2 and CM3 may be formed on the lower interlayer insulating layer 195.

Since forming the lower insulating barrier layer 194, the lower interlayer insulating layer 195 and the contact plugs 183 and 283 on the lower interlayer insulating layer 193 may be substantially the same as forming the contact plugs 182 and 282 described with reference to FIGS. 18A and 18B, detailed descriptions thereof will be omitted.

Forming an insulating structure 46 and the circuit interconnection pattern CM1 on the lower interlayer insulating layer 195 may be performed by repeating a process of sequentially forming an insulating barrier layer 48 and an intermetallic insulating layer 50 and forming a circuit interconnection pattern using a damascene process within the insulating barrier layer 48 and the intermetallic insulating layer 50. The process may be repeated to form the insulating structures 56 and 66 and the circuit interconnection patterns CM2 and CM3 on the insulating structure 46 and the circuit interconnection pattern CM1.

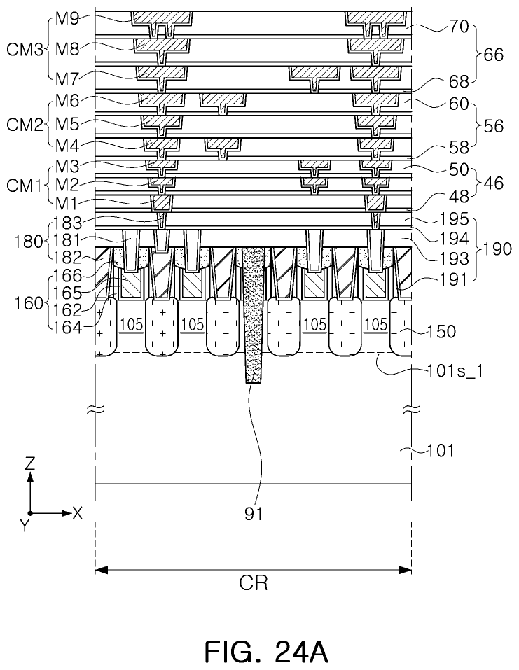

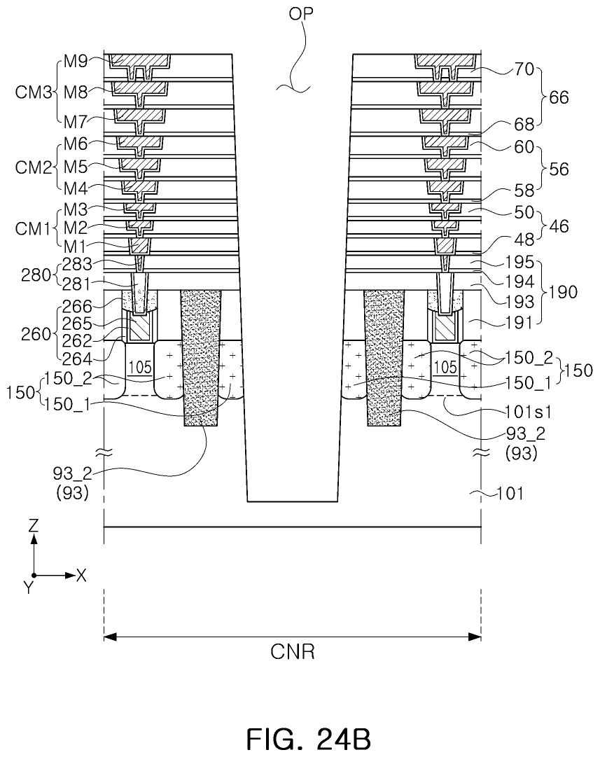

Referring to FIGS. 24A and 24B, an open region OP may be formed in the connection region CNR of the substrate 101. The open region OP may be formed after forming a predetermined mask pattern layer on the insulating structure 66. Referring to FIG. 2B together, the open region OP may be a region corresponding to the through-region THR.

A lower end of the open region OP may be formed in a position lower than a position of a lower end of the separation structure 93.

At least a portion of the first separation structure 93_1 may be removed by the open region OP. Referring to FIG. 2B together, the at least portions of the first separation structure 93_1 may be spaced apart from each other in the second direction, for example, the Y-direction, by the open region OP.

Additionally, at least a portion or all of the first source/drain region 150_1 may be removed by the open region OP.

Accordingly, at least a portion of a side surface of the first separation structure 93_1 and at least a portion of a side surface of the first source/drain region 150_1 may be exposed by the open region OP.

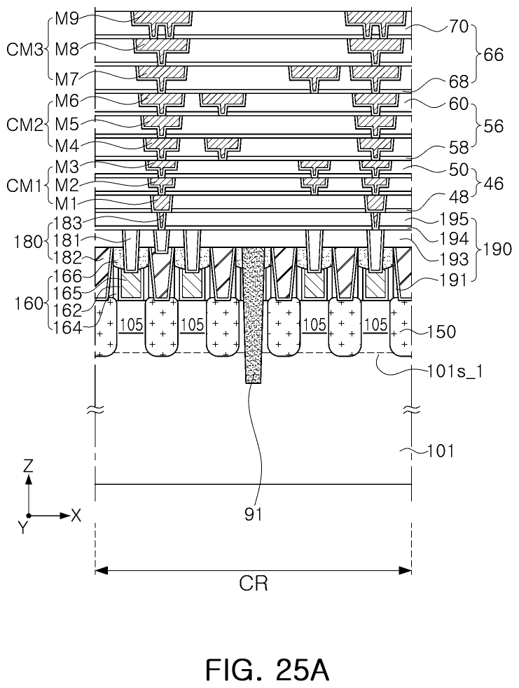

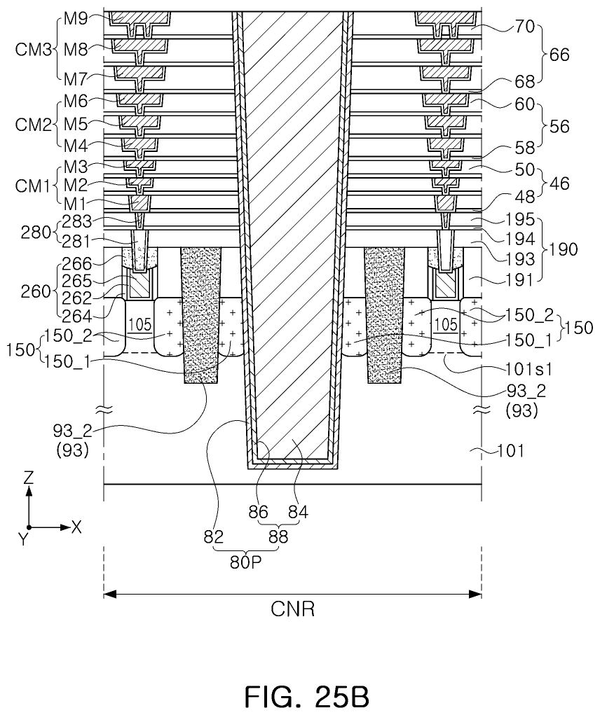

Referring to FIGS. 25A and 25B, a preliminary through-electrode structure 80P may be formed by sequentially forming an insulating spacer 82, a conductive barrier layer 86 and a pillar pattern 84 in the open region OP.

The insulating spacer 82 may be formed by conformally depositing an insulating material on a sidewall of the open region OP and an upper surface of the insulating structure 66. Then, the conductive barrier layer 86 may be formed by conformally depositing a conductive material on the insulating spacer 82. Then, a conductive material, such as copper (Cu), may be formed to fill the open region OP.

Then, portions of the insulating material and the conductive material formed to be higher than an upper surface of the insulating structure 66 may be removed through a CMP process so as to expose the upper surface of the insulating structure 66. Accordingly, copper (Cu) filling the open region OP may have a pillar pattern.

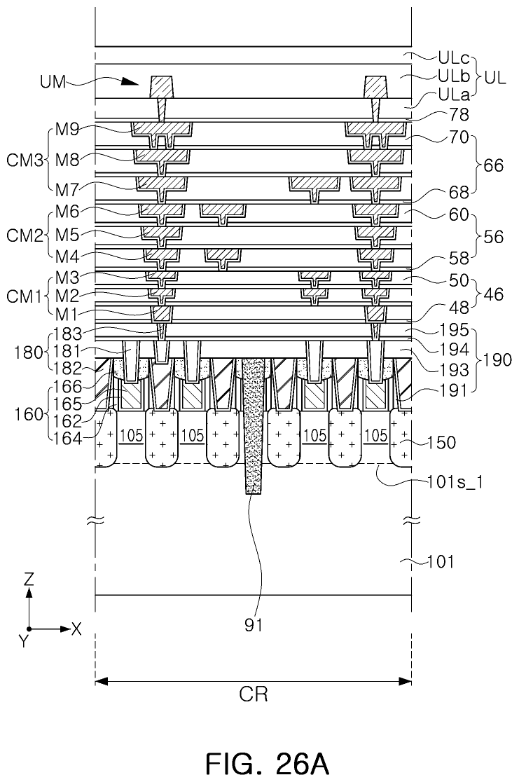

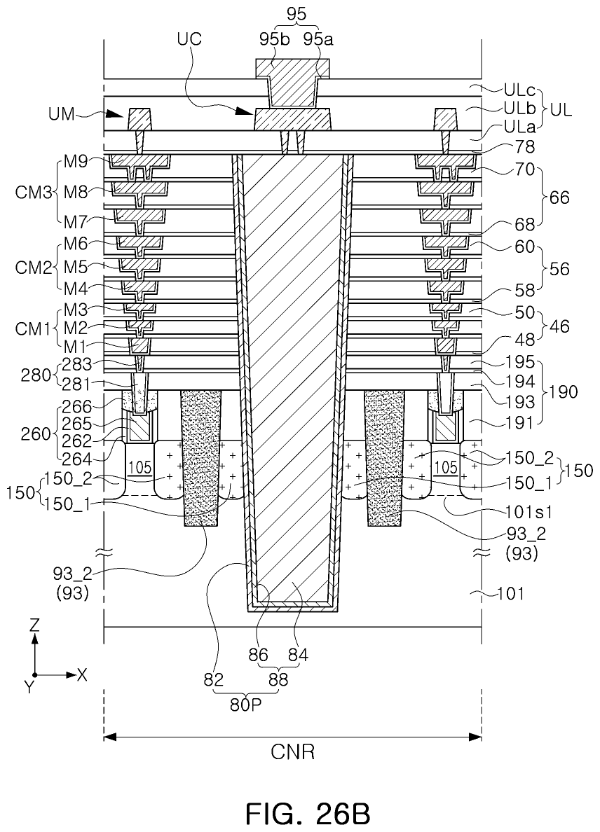

Referring to FIGS. 26A and 26B, a preliminary semiconductor device may be formed by forming an upper insulating structure UL, an upper circuit pattern UM, and a front pad 95 on the insulating structure 66 and the preliminary through-electrode structure 80P.

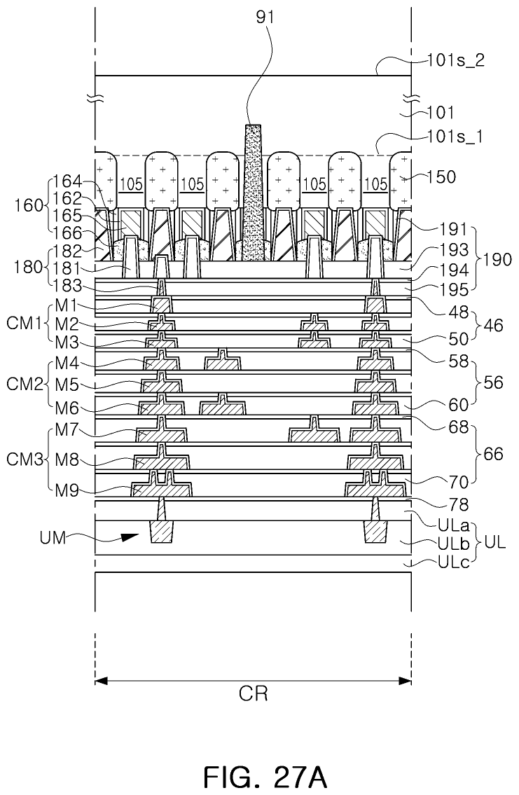

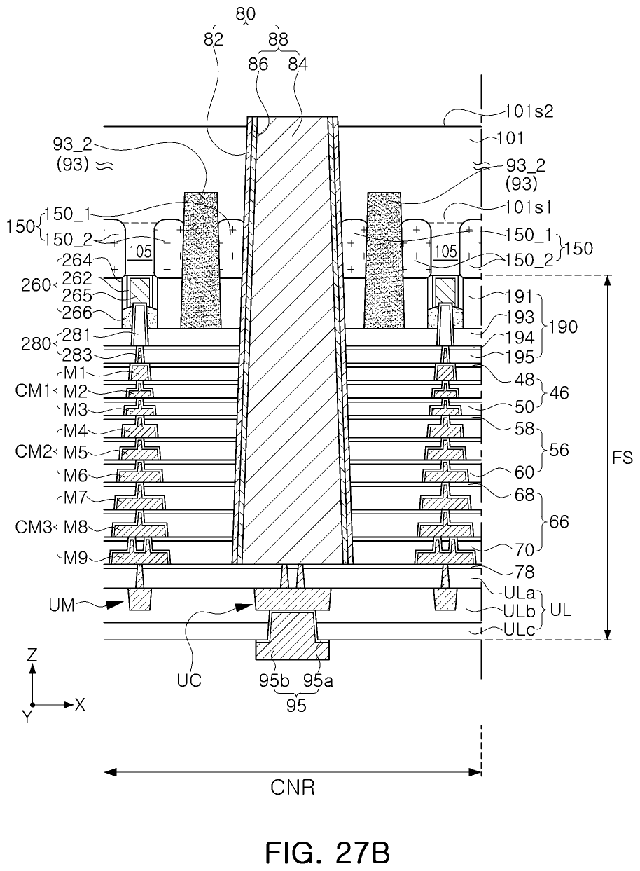

Referring to FIGS. 27A and 27B, the preliminary semiconductor device according to FIGS. 26A and 26B may face up, and a backside surface of the substrate 101 may be ground and etched so that an upper surface of the preliminary through-electrode structure 80P protrudes from the second surface 101s_2 of the substrate 101.

Hereafter, referring to FIGS. 1A and 1B together, a backside insulating layer 97 covering the second surface 101s_2 of the substrate 101 may be formed, and the backside insulating layer 97 may be flattened.

Subsequently, a backside conductive pattern 99 electrically connected to the through-electrode structure 80 may be formed by sequentially forming a first conductive layer 99a and a second conductive layer 99b on the backside insulating layer 97.

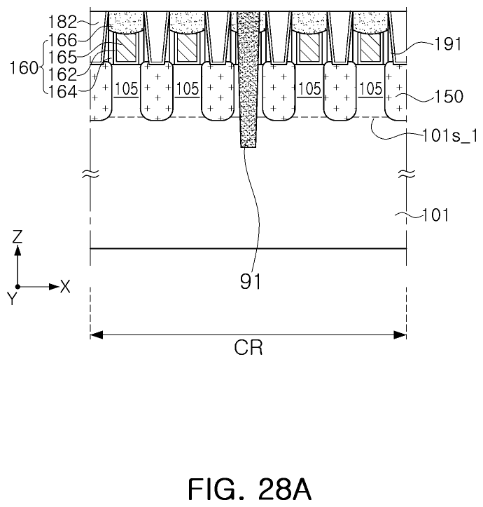

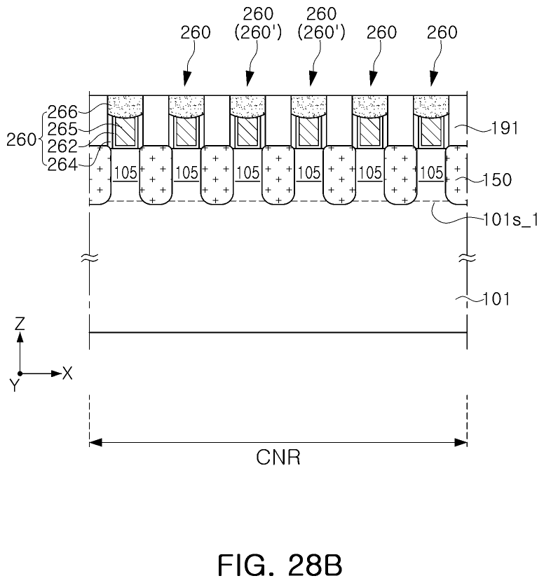

FIGS. 28A to 33B are vertical cross-sectional views illustrating a method of manufacturing a semiconductor device 100e according to an example embodiment of the present inventive concept. As described above with reference to FIGS. 7 and 8, the cell region CR of the semiconductor device 100e may have substantially the same characteristics as the cell region CR of the semiconductor device 100a described with reference to FIG. 1A. Accordingly, FIGS. 28A, 29A, 30A, 31A, 32A and 33A may be drawings corresponding to FIG. 1A, and FIGS. 28B, 29B, 30B, 31B, and 32B may be drawings corresponding to FIG. 7.

Each of FIGS. 28A and 28B may be a process diagram continuing from each of the processes of FIGS. 18A and 18B.

Referring to FIGS. 28A and 28B, similarly to what was described with reference to FIGS. 19A and 19B to 21A and 21B, a separation structure 91 may be formed between the gate structures 160.

According to an example embodiment of the present inventive concept, no separation structure may be formed between the gate structures 260.

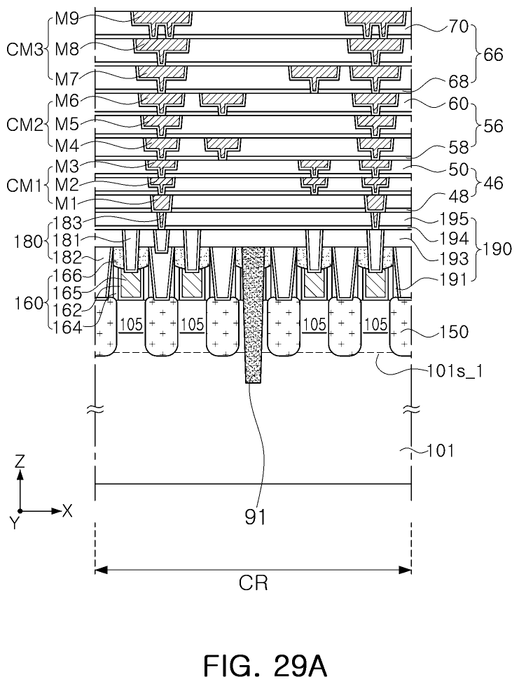

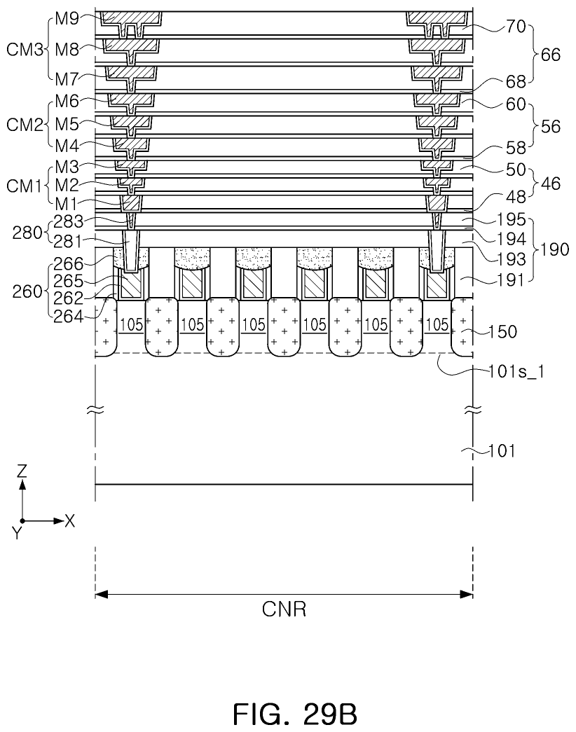

Referring to FIGS. 29A and 29B, similarly to what was described with reference to FIGS. 23A and 23B, a lower interlayer insulating layer 193, contact plugs 181 and 281, a lower insulating barrier layer 194, a lower interlayer insulating layer 195, contact plugs 183 and 283, insulating structures 46, 56 and 66, and circuit interconnection patterns CM1, CM2 and CM3 may be formed on the gate structures 160 and 260 and the lower interlayer insulating layer 191.

Since this may be substantially the same as what was described with reference to FIGS. 23A and 23B, detailed descriptions thereof will be omitted.

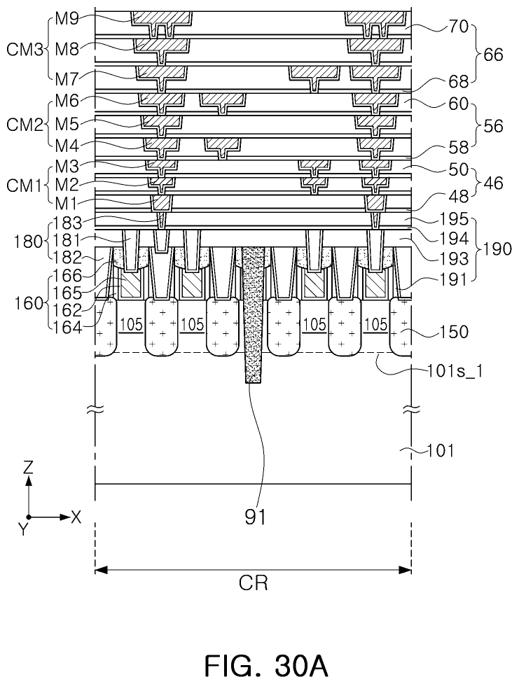

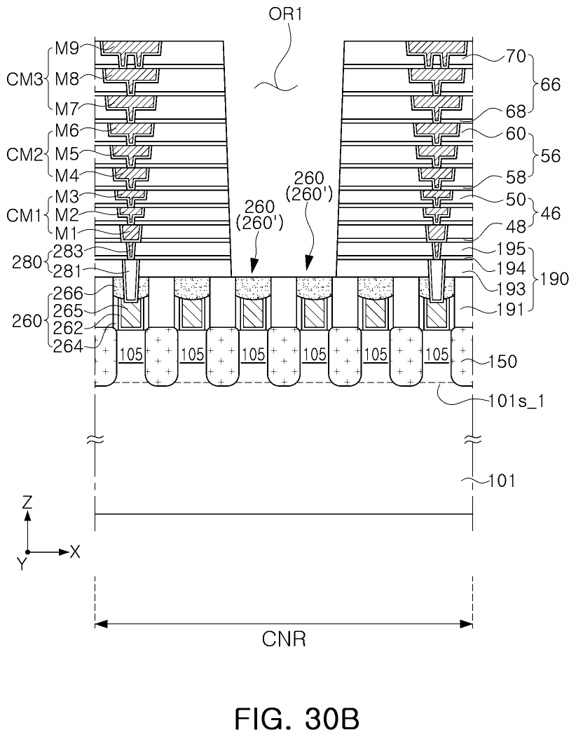

Referring to FIGS. 30A and 30B, a first open region ORI may be formed on the gate structures 260′, which is to be removed.

The first open region ORI may be formed by forming a predetermined mask pattern layer on the insulating structure 66 and penetrating through at least a portion of the first to third insulating structures 46, 56 and 66 so that at least portions of an upper surface of some of the gate structures 260 and an upper surface of the lower interlayer insulating layer 191 are exposed.

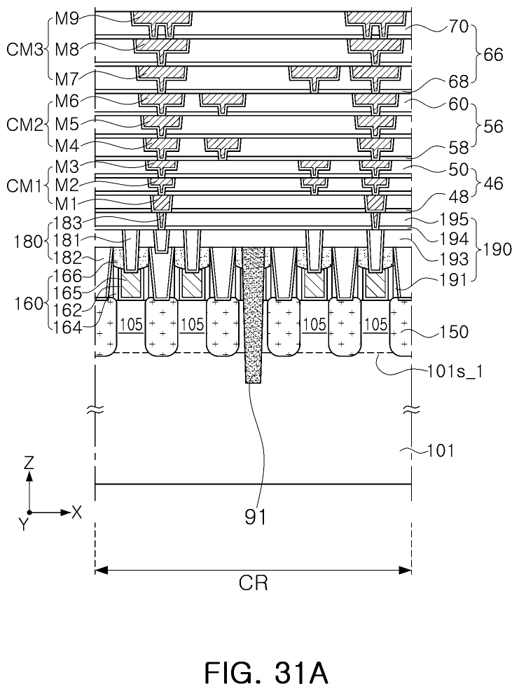

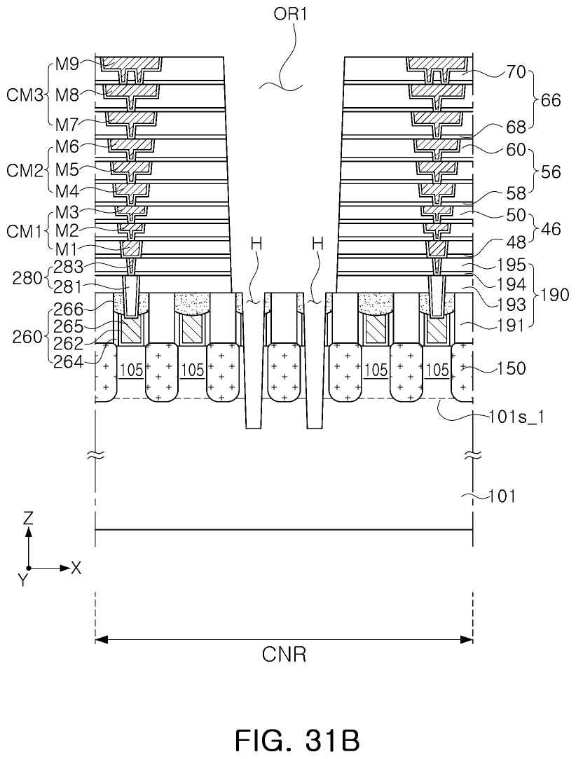

Referring to FIGS. 31A and 31B, trenches H penetrating through the exposed gate structures 260′, which are to be removed in the first open region OR1, may be formed.

The exposed gate structures 260′, which are to be removed, may be selectively removed with respect to the lower interlayer insulating layer 191 to form the trenches H. Gate electrode layers 265 of the gate structures 260′, which are to be removed, may be removed by the trenches H.

When the gate electrode layers 265 include a conductive material and the insulating structure 66 and the gate electrode layers 265 are removed through a single etching process, the conductive material may cause contamination in semiconductor processing equipment. Accordingly, in this example embodiment, the insulating structure 66 and the gate electrode layers 265 may be sequentially removed.

Lower ends of the trenches H may be formed to extend below lower ends of the source/drain region 150. Interiors of the trenches H might not be filled with additional materials.

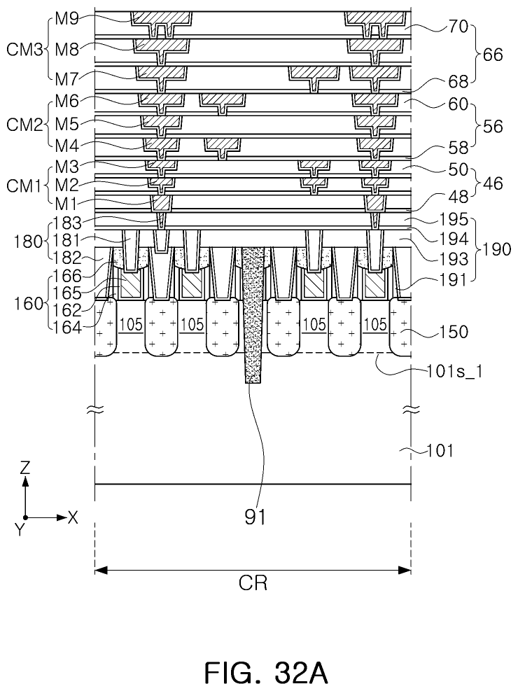

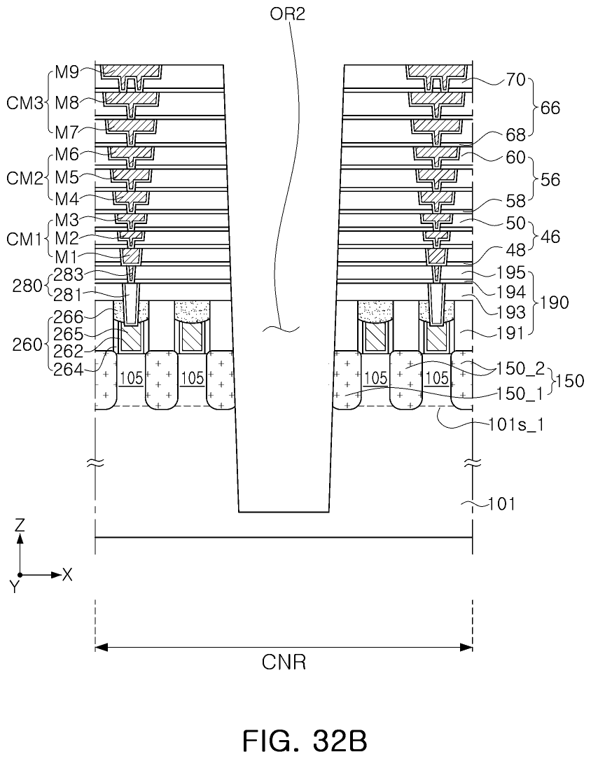

Referring to FIGS. 32A and 32B, a second open region OR2 may be formed on the trenches H.

The second open region OR2 may be formed within the first open region OR1. Accordingly, the trenches H may be removed by the second open region OR2.

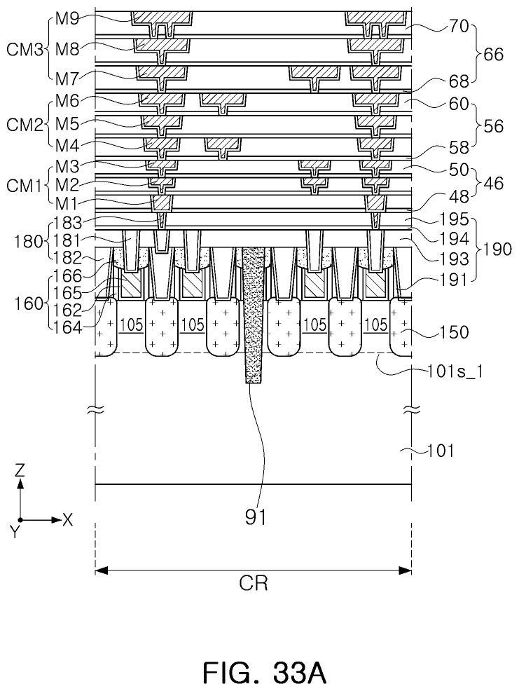

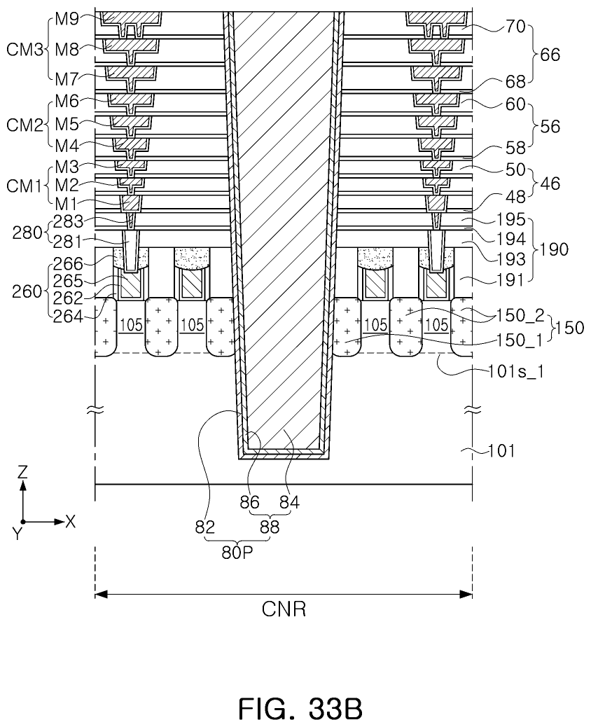

Referring to FIGS. 33A and 33B, similarly to what was described with reference to FIGS. 25A and 25B, a preliminary through-electrode structure 80P may be formed by sequentially forming an insulating spacer 82, a conductive barrier layer 86, and a pillar pattern 84 in the second open region OR2.

Since the preliminary through-electrode structure 80P may be formed through substantially the same process as described with reference to FIGS. 22A and 22B, detailed descriptions thereof will be omitted.

Then, the semiconductor device 100e may be formed through the same process as described with reference to FIGS. 26A and 26B and FIGS. 27A and 27B.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device, comprising:
a substrate comprising a cell region and a connection region and extending in a first direction, wherein the substrate has a first surface and a second surface opposing each other, wherein the connection region comprises a through-region, and has a first side and a second side opposing each other in the first direction with the through-region interposed therebetween;
active regions protruding vertically from the first surface of the substrate, in a first region, which is adjacent to the first side of the connection region, and a second region, which is adjacent to the second side of the connection region;
source/drain regions spaced apart from each other on the substrate in the first direction, wherein the source/drain regions include:
first source/drain regions having a portion at least partially overlapping the through-region, and
second source/drain regions disposed on at least one side of the active regions on the substrate;
first gate structures intersecting the active regions and disposed on the active regions, wherein the first gate structures include a gate electrode and a gate capping layer on the gate electrode, and extends in a second direction;
a front structure including a front conductive pattern disposed on the first surface of the substrate;
a backside structure including a backside conductive pattern disposed on the second surface of the substrate; and
a through-electrode structure extending by filling the through-region of the substrate, and electrically connected to the front conductive pattern of the front structure and the backside conductive pattern of the backside structure, and
wherein at least a portion of a side surface of a lower region of the through-electrode structure is in contact with the first source/drain regions.

2. The semiconductor device of claim 1, wherein the first gate structures are dummy gate structures that are electrically insulated from the cell region.

3. The semiconductor device of claim 1, wherein a horizontal width of the through-electrode structure decreases from an upper surface thereof that is in contact with the front conductive pattern of the front structure to a lower surface thereof that is in contact with the backside conductive pattern of the backside structure.

4. The semiconductor device of claim 1, further comprising:
second gate structures between the first region and the second region,
wherein the second gate structures are in contact with at least a portion of a side surface of the lower region of the through-electrode structure.

5. The semiconductor device of claim 4, further comprising:
contact plugs disposed between the first and second gate structures that are adjacent to each other and between the second gate structures that are adjacent to each other,
wherein the contact plugs are in contact with a portion of the side surface of the lower region of the through-electrode structure.

6. The semiconductor device of claim 1, wherein the through-electrode structure includes:
a first portion having an upper surface on substantially the same level as upper surfaces of the first gate structures,
a second portion on the first portion, wherein the second portion has a lower surface on substantially the same level as the upper surfaces of the first gate structures, and
a width of the upper surface of the first portion is larger than a width of the lower surface of the second portion.

7. The semiconductor device of claim 1, further comprising:
a first separation structure disposed between the first source/drain regions that are adjacent to each other on the substrate, and extending in the second direction,
wherein the first separation structure is in contact with at least a portion of the side surface of the lower region of the through-electrode structure.

8. The semiconductor device of claim 7, wherein side surfaces of the first separation structure are in contact with the first source/drain regions that are adjacent to each other, respectively.

9. The semiconductor device of claim 7, wherein a portion of the side surface of the lower region of the through-electrode structure is in contact with a side surface of the first separation structure.

10. The semiconductor device of claim 9, wherein the source/drain regions further include third source/drain regions that are disposed between the first and second source/drain regions, and
the semiconductor device further includes a second separation structure disposed between the third source/drain regions that are adjacent to each other on the substrate and between the second source/drain region and the third source/drain region that are adjacent to each other, and extending in the second direction,
wherein the second separation structure is spaced apart from the through-region in the first direction.

11. The semiconductor device of claim 7, wherein a maximum horizontal width of the through-electrode structure is about 1 um to about 6 um, and
a maximum horizontal width of the first separation structure is about 5 nm to about 20 nm.

12. The semiconductor device of claim 1, further comprising:
a plurality of channel layers spaced apart from each other in a vertical direction, which is substantially perpendicular to the first surface of the substrate,
wherein each of the first gate structures at least partially surrounds the plurality of channel layers.

13. The semiconductor device of claim 1, wherein the through-electrode structure includes:
a pillar pattern;
a conductive barrier layer configured to cover an outer surface of the pillar pattern; and
an insulating spacer configured to cover an outer surface of the conductive barrier layer.

14. A semiconductor device, comprising:
a substrate comprising a cell region and a dummy region and extending in a first direction, wherein the substrate has a first surface and a second surface opposing each other, wherein the dummy region comprises a through-region, and has a first side and a second side opposing each other in the first direction with the through-region interposed therebetween;
active regions protruding vertically from the first surface of the substrate, in a first region, which is adjacent to the first side of the dummy region, and a second region, which is adjacent to the second side of the dummy region;
source/drain regions spaced apart from each other on the substrate in the first direction, wherein portions of the source/drain regions are on at least one side of the active regions on the substrate;
dummy gate structures intersecting the active regions on the active regions, and including a gate electrode and a gate capping layer on the gate electrode, wherein the dummy gate structures extend in a second direction;
a front structure including a front conductive pattern disposed on the first surface of the substrate;
a backside structure including a backside conductive pattern disposed on the second surface of the substrate;
a separation structure disposed between the source/drain regions that are adjacent to each other between the first region and the second region, and extending on the substrate in the second direction; and
a through-electrode structure extending by filling the through-region of the substrate, and contacting the front conductive pattern of the front structure and the backside conductive pattern of the backside structure,
wherein at least a portion of the separation structure is in contact with at least a portion of an external circumferential surface of the through-electrode structure in the through-region.

15. The semiconductor device of claim 14, wherein a lower end of the separation structure is on a level that is between lower ends of the source/drain regions and a lower end of the through-electrode structure.

16. The semiconductor device of claim 14, wherein the separation structure further includes at least one insulating pattern disposed on a side surface of an upper region of the separation structure, and
the separation structure and the at least one insulating pattern are in contact with at least a portion of the external circumferential surface of the through-electrode structure.

17. The semiconductor device of claim 16, wherein the at least one insulating pattern includes a plurality of insulating patterns, and
the plurality of insulating patterns include a first insulating pattern, which is disposed on the side surface of the upper region of the separation structure, and a second insulating pattern, which is disposed on the first insulating pattern.

18. The semiconductor device of claim 14, further comprising:
a separation pattern disposed on at least one side of the separation structure and in contact with at least a portion of the external circumferential surface of the through-electrode structure,
wherein a lower end of the separation pattern recesses an upper region of the source/drain regions.

19. A semiconductor device, comprising:
a substrate comprising a cell region and a connection region and extending in a first direction, wherein the substrate has a first surface and a second surface opposing each other, wherein the connection region comprises a through-region, and has a first side and a second side opposing each other in the first direction with the through-region interposed therebetween;
active regions protruding vertically from the first surface of the substrate, in a first region, which is adjacent to the first side of the connection region, and a second region, which is adjacent to the second side of the connection region;
impurity regions in which at least some thereof is on at least one side of the active regions on the substrate, wherein the impurity regions are spaced apart from each other on the substrate in the first direction;
a front structure including a front conductive pattern disposed on the first surface of the substrate;
a backside structure including a backside conductive pattern disposed on the second surface of the substrate;
separation structures disposed between the impurity regions that are adjacent to each other between the first region and the second region, and extending on the substrate in a second direction; and
a through-electrode structure extending by filling the through-region of the substrate, and electrically connecting the front structure and the backside structure to each other,
wherein at least a portion of the separation structures is in contact with at least a portion of an external circumferential surface of the through-electrode structure in the through-region.

20. The semiconductor device of claim 19, further comprising:
gate structures intersecting the substrate on the active regions, and including a gate electrode and a gate capping layer on the gate electrode, wherein the gate structures extend in the second direction.
